(19) United States
(12) Patent Application Publication
(10) Pub. No.: US 2016/0020225 A1
(43) Pub. Date: Jan. 21, 2016

(54) NONVOLATILE SEMICONDUCTOR MEMORY DEVICE

(71) Applicant: KABUSHIKI KAISHA TOSHIBA, Tokyo (JP)

(72) Inventors: Wataru SAKAMOTO, Yokkaichi Mie (JP); Kenta YAMADA, Yokkaichi Mie (JP)

(21) Appl. No.: 14/633,014

(22) Filed: Feb. 26, 2015

Related U.S. Application Data
(60) Provisional application No. 62/027,068, filed on Jul. 21, 2014.

(51) Int. Cl. H01L 27/12; H01L 29/04; H01L 27/115

(52) U.S. Cl. CPC H01L 27/1207; H01L 27/11524; H01L 29/04

(57) ABSTRACT

A nonvolatile semiconductor memory device includes a plurality of memory strings including a plurality of memory transistors connected in series and a selection transistor disposed on either end of the plurality of memory transistors, which together form a memory cell. The memory transistors and the selection transistors each include a polysilicon layer formed on an insulating film as a channel region thereof. A drain region is in a first diffusion layer region in the polysilicon layer in a location adjacent to a selection transistor at a first end of the memory string, and a source region is in a second diffusion layer region in the polysilicon layer in a location adjacent to a selection transistor at a second end of the memory string. In at least one of the first and the second diffusion regions, the grain size of the polysilicon is smaller than in other portions of the polysilicon.

### CROSS-REFERENCE TO RELATED APPLICATION

This application is based upon and claims the benefit of priority from U.S. Provisional Patent Application No. 62/027,068, filed Jul. 21, 2014, the entire contents of which are incorporated herein by reference.

### FIELD

Embodiments described herein relate to a nonvolatile semiconductor memory device.

### BACKGROUND

In nonvolatile semiconductor memory devices, for example, NAND flash memory device including a floating channel configured as a simple stacked NAND flash memory device or a vertical NAND flash memory device, it is difficult to directly apply an erasing voltage onto a channel portion of a memory cell of an upper layer formed on an insulating film, and thus it is difficult to remove electrons from a charge storage layer (a floating gate) at the time of performing data erasing. In addition, in the memory cell of the upper layer, cutoff characteristics of a selection transistor are degraded, and thus the off current of a memory string of a non-selection block increases.

### BRIEF DESCRIPTION OF THE DRAWINGS

FIG. 1 is an example of a longitudinal sectional view illustrating a sectional structure of a memory cell region of a stacked NAND type flash memory device according to a first embodiment.

FIG. 2 is an example of an equivalent circuit diagram illustrating a part of a memory cell array.

FIG. 3 is an example of a band diagram schematically illustrating a potential of an end of a diffusion layer region of a selection transistor.

FIG. 4 is an example of a diagram illustrating a result of performing a simulation with respect to a change in a potential.

FIG. 5 to FIG. 11 are examples of a longitudinal sectional view illustrating the NAND flash memory device according to the first embodiment during steps of manufacturing thereof.

FIG. 12 is an example of a perspective view illustrating a structure of a vertically stacked NAND type flash memory device according to a second embodiment.

FIG. 13 to FIG. 22 are examples of a longitudinal sectional view illustrating the vertically stacked NAND type flash memory device according to the second embodiment during steps of manufacturing thereof.

FIG. 23 to FIG. 28 are examples of a longitudinal sectional view illustrating a vertically stacked NAND type flash memory device according to a third embodiment during steps of manufacturing thereof.

FIG. 29, and FIG. 31 to FIG. 33 are examples of a longitudinal sectional view illustrating a stacked NAND type flash memory device according to a fourth embodiment during steps of manufacturing thereof.

FIGS. 30A and 30B are diagrams describing a result of performing a simulation with respect to a change in cutoff characteristics.

FIG. 34 is an example of a longitudinal sectional view illustrating a structure of a stacked NAND type flash memory device according to a fifth embodiment.

FIG. 35 is a diagram illustrating an example of a bias condition.

FIG. 36 is an example of a longitudinal sectional view illustrating a structure of a stacked NAND type flash memory device according to a sixth embodiment.

FIG. 37 is an example of a longitudinal sectional view illustrating a structure of a stacked NAND type flash memory device according to a seventh embodiment.

FIG. 38 is an example of a diagram illustrating an aspect of a variation in a plurality of threshold value distributions at the time of using a stacked NAND type flash memory device as a multivalued memory.

### DETAILED DESCRIPTION

According to one embodiment, a nonvolatile semiconductor memory device includes a plurality of memory strings including a plurality of memory transistors connected in series and a selection transistor disposed on either end of the plurality of memory transistors, which together form a memory cell. The memory transistors and the selection transistors each include a polysilicon layer formed on an insulating film as a channel region thereof. A drain region is in a first diffusion layer region in the polysilicon layer in a location adjacent to a selection transistor at a first end of the memory string, and a source region is in a second diffusion layer region in the polysilicon layer in a location adjacent to a selection transistor at a second end of the memory string. In at least one of the first and the second diffusion regions, the grain size of the polysilicon is smaller than in other portions of the polysilicon.

### First Embodiment

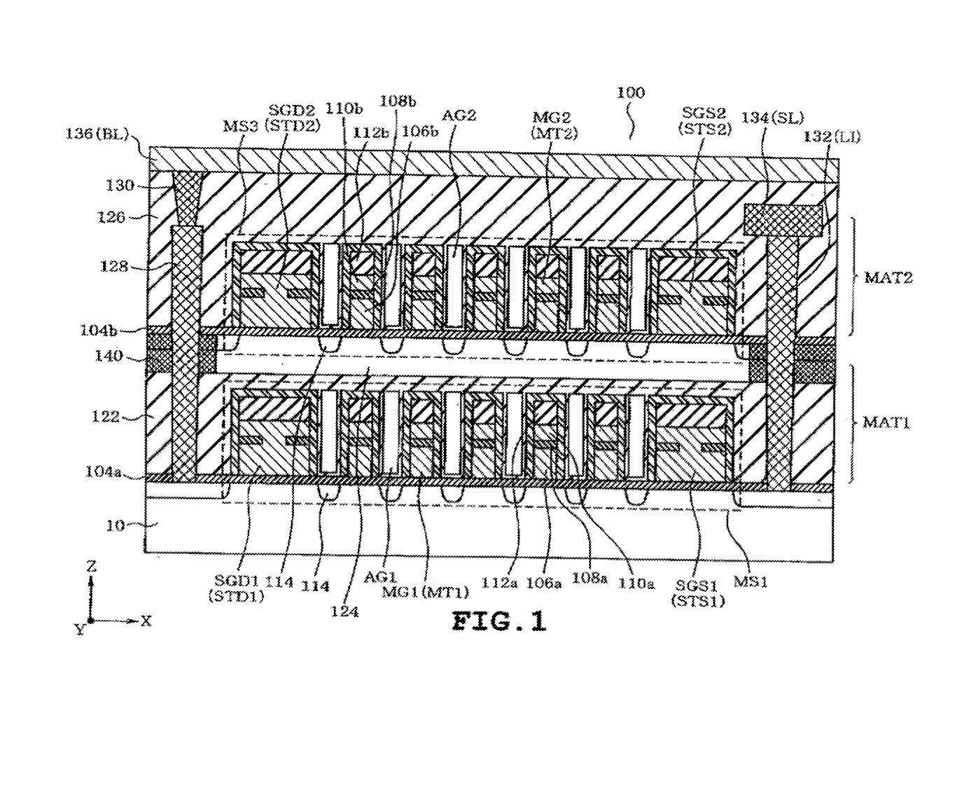

Hereinafter, a first embodiment in which a simple stacked NAND flash memory device is applied to a semiconductor memory device as a nonvolatile semiconductor memory device will be described with reference to FIG. 1 to FIG. 11. In the following description, the same reference numerals are applied to elements having the same function and the same configuration. The drawings are schematically illustrated, and a relationship between a thickness and a plane dimension, a ratio of thicknesses of each layer, or the like is not necessarily coincident with those of an actual device. In addition, vertical and horizontal directions indicate a relative direction when a circuit formation surface side in a semiconductor substrate described later is set to an upper side, and are not necessarily coincident with a case where the directions are based on a gravitational acceleration direction. Furthermore, in the following description, for the sake of simplicity of the description, an XYZ orthogonal coordinate system is used. In the coordinate system, two directions orthogonal to each other in a direction parallel with a surface of the semiconductor substrate are set to an X direction and a Y direction, and a direction in which a bit line BL extends is chosen as the X direction, and a direction orthogonal to the X direction in which a word line WL extends is chosen as the Y direction. A direction orthogonal to both the X direction and the Y direction is the Z direction.

FIG. 1 is an example of a longitudinal sectional view illustrating a sectional structure of a memory cell region of a simple stacked NAND flash memory device 100 according to the first embodiment.

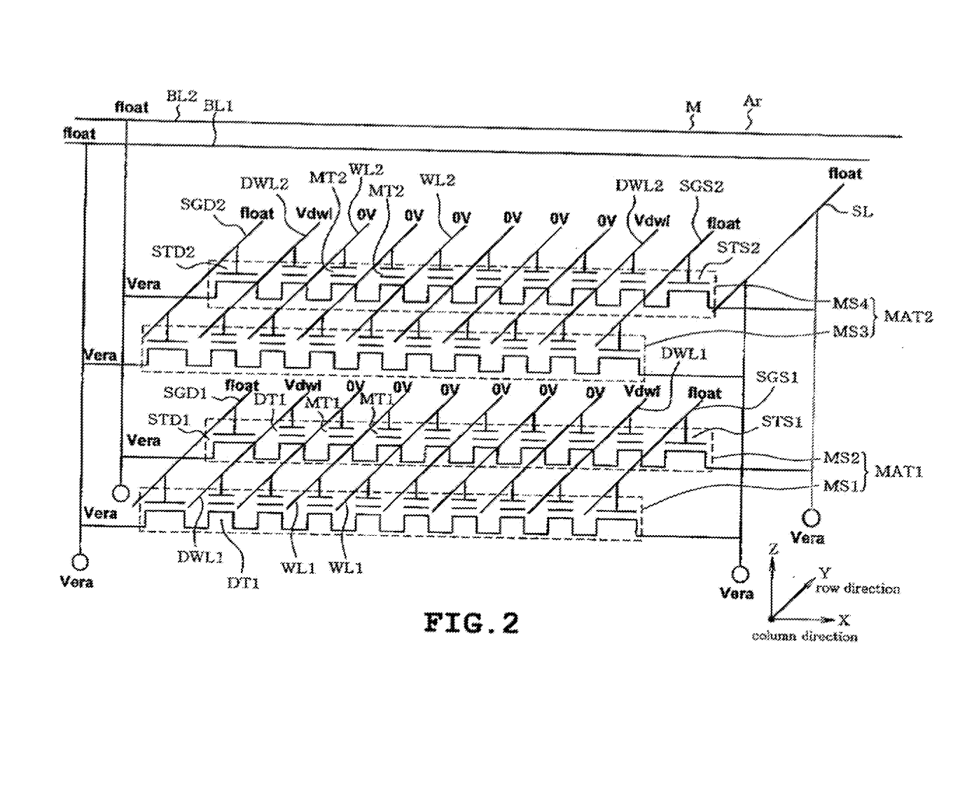

As illustrated in FIG. 1, an insulating film 104a is formed on a semiconductor substrate 10. On the insulating film 104a, a plurality of memory gates MG1 are formed generally in a line, and selection gate electrodes SGD1 and SGS1 are formed adjacent to both ends of the plurality of memory gates MG1. Corresponding memory cell transistors MT1 are configured with the plurality of memory gates MG1, and selection transistors STD1 and STS1 disposed on both ends of the corresponding line of memory cell transistors MT1 are configured with the selection gate electrodes SGD1 and SGS1, to form one memory string MS1. Within the memory string MS1, each memory cell transistors MT1 is connected in series by sharing a diffusion layer region with the adjacent memory cell transistor MT1. Among the plurality of memory gates MG1, the memory gates MG1 on the both ends of the memory string MS1 may be a dummy gate (a dummy word line DWL described later). In FIG. 1, one memory string MS1 formed on the semiconductor substrate 10 is illustrated, but as illustrated in FIG. 2 described later herein, a plurality of memory strings MS1 are formed, and the plurality of memory strings MS1 together form a memory mat MAT1.

Each one of the plurality of memory gates MG1 includes a lower electrode 106a, an inter-electrode insulating film 108a, an upper electrode 110a, and a cap film 112a which are stacked in that order on the insulating film 104a. The memory gate MG1 functions as a gate electrode of the memory cell transistor MT1. The insulating film 104 functions as a tunnel insulating film of the memory cell transistor MT1. The lower electrode 106a functions as a floating gate (a charge accumulation region) of the memory gate MG1. The upper electrode 110a functions as a control gate of the memory gate MG1. The inter-electrode insulating film 108a is disposed between the lower electrode 106a and the upper electrode 110a, and insulates the lower electrode 106a and the upper electrode 110a from each other.

The selection gate electrodes SGD1 and SGS1 include the lower electrode 106a, the inter-electrode insulating film 108a, the upper electrode 110a, and the cap film 112a which are stacked in that order on the insulating film 104a. The selection gate electrodes SGD1 and SGS1 function as a gate electrode of the selection transistors STD1 and STS1. The insulating film 104a functions as a gate insulating film of the selection transistors STD1 and STS1. An opening is provided in a center portion of the inter-electrode insulating film 108 I the selection transistors STD1 and SGS1, and thus the lower electrodes 106a and the upper electrodes 110a thereof are electrically connected to each other, and integrally function as the gate electrode of the selection transistors STD1 and STS1. A gap AG1, which may be an “air gap”, is formed between the memory gates MG1, between the memory gate MG1 and the selection gate electrode SGD1, and between the memory gate MG1 and the selection gate electrode SGS1.

An interlayer insulating film 122 is formed to cover an upper surface and a side surface of the string of memory gates MG1 and the selection gate electrodes SGD1 and SGS1 which are disposed on the semiconductor substrate 10. An upper surface of the interlayer insulating film 122 is flattened, and a channel polysilicon layer 124 is formed on the flattened upper surface thereof.

An insulating film 104b is formed on the channel polysilicon layer 124. A plurality of memory gates MG2 formed along a line to form a string of memory gates MG2, and selection gate electrodes SG2 adjacent to either ends of the plurality of memory gates MG2 are formed on the insulating film 104b. Memory cell transistors MT2 configured with the plurality of memory gates MG2, and selection transistors STD2 and STS2 configured with the selection gate electrodes SGD2 and SGS2, together form one memory string MS2. In the memory string MS2, each memory cell transistor MT2 except the first and last on the string is connected in series with another memory cell transistor MT2 by sharing a source and drain region with the adjacent memory cell transistor MT2.

The memory gate MG2 includes a lower electrode 106b, an inter-electrode insulating film 108b, an upper electrode 110b, and a cap film 112b which are stacked in that order on the insulating film 104b. The memory gate MG2 functions as a gate electrode of the memory cell transistor MT2. The insulating film 104b functions as a tunnel insulating film of the memory cell transistor MT2. The lower electrode 106b functions as a floating gate (an accumulation electrode) of the memory gate MG2. The upper electrode 110b functions as a control gate of the memory gate MG2. The inter-electrode insulating film 108b is disposed between the lower electrode 106b and the upper electrode 110, and insulates the lower electrode 106b and the upper electrode 110b from each other.

The selection gate electrodes SGD2 and SGS2 each include the lower electrode 106b, the inter-electrode insulating film 108b, the upper electrode 110b, and the cap film 112b which are stacked on the insulating film 104b. The selection gate electrodes SGD2 and SGS2 function as the gate electrode of the selection transistors STD2 and STS2. The insulating film 104b functions as a gate insulating film of the selection transistors STD2 and STS2. An opening is provided in a center portion of the inter-electrode insulating film 108b, and thus the lower electrode 106b and the upper electrode 110b are electrically connected to each other. A gap AG2 (such as an “air gap”) is formed between the memory gates MG2, between the memory gate MG2 and the selection gate electrode SGD2, and between the memory gate MG2 and the selection gate electrode SGS2.

In the channel polysilicon layer 124, a defect layer region 140 is disposed at either end (in the drawing, when the X direction is established as the horizontal direction, to a left side of the selection gate electrode SGD2 and to the right side of the selection gate electrode SGS2) of the memory string MS2. The defect layer region 140 is a diffusion layer region of the selection transistors STD2 and STS2. The channel polysilicon layer 124 and the defect layer region 140, for example, are formed of polysilicon. Crystallinity of the polysilicon is excellent in the channel polysilicon layer 124, and a grain diameter (grain size) of the polysilicon of the channel polysilicon layer 124 is greater than a grain diameter (grain size) of the polysilicon of the defect layer region 140. Germanium (Ge) and carbon (C) are introduced into the defect layer region 140. Any one of germanium and carbon may be introduced into the defect layer region 140.

In FIG. 1, one memory string MS2 formed on the channel polysilicon layer 124 is exemplarily illustrated, but as illustrated in FIG. 2 described later herein, a plurality of memory strings MS2 is formed, and the plurality of memory strings MS2 form a memory mat MAT2.

An interlayer insulating film 126 covers the string of memory gates MG2, and the selection gate electrodes SGD2 and SGS2. A surface of the interlayer insulating film 126 is flattened. Wiring 134 is disposed in the interlayer insulating film 126. The wiring 134 is a source line SL, and a contact plug 132 is formed from a lower portion of the wiring 134 to the surface of the semiconductor substrate 10 by extending through the interlayer insulating film 126, the defect layer region 140, and the interlayer insulating film 122.

On the other hand, wiring 136 is disposed on the interlayer insulating film 126. The wiring 136 is a bit line BL, and an electrode 130 is formed by being connected to a lower portion of the wiring 136. A contact plug 128 is formed from a lower surface of the electrode 130 to the surface of the semiconductor substrate 10 and extends through the interlayer insulating film 126, the defect layer region 140, and the interlayer insulating film 122. As described above, in the memory mat MAT2, an active region (a diffusion layer region and a channel region) of the memory cell transistor MT and the selection transistor ST has a Silicon on Insulator (SOI) structure.

FIG. 2 is an example of an equivalent circuit diagram of a part of a memory cell array formed in a memory cell region of the simple stacked NAND flash memory device 100 according to the first embodiment. As illustrated in FIG. 2, the simple stacked NAND flash memory device 100 includes a memory cell array Ar in which a plurality of memory cells are three-dimensionally disposed in matrix in a memory cell region M.

In the memory cell array Ar, the memory mats MAT1 and MAT2 are disposed as two memory cell layers, an upper and a lower stage. In the memory mat MAT1, a plurality of word lines WL1 extending in a row direction (in the drawing, the Y direction) are disposed in parallel spaced in a column direction (in the drawing, the X direction). In the column direction (in the drawing, the X direction), the adjacent memory cell transistors MT1 are connected in series such that adjacent memory cell transistors MT1 share their intermediate diffusion layer regions, and one end thereof is connected to a dummy transistor DT1 and the selection transistor STD1 on the bit line side. The other end is connected to the dummy transistor DT1 and the selection transistor STS1 on the source line side. The selection transistors STD1 and STS1, and a plurality of dummy transistors DT1 and the memory cell transistor MT1 sandwiched therebetween configure the memory strings MS1 and MS2.

In the memory mat MAT2, a plurality of word lines WL2 extending in the row direction (in the drawing, the Y direction) are disposed in parallel and spaced in the column direction (in the drawing, the X direction). In the column direction (in the drawing, the X direction), the adjacent memory cell transistors MT2 are disposed by being connected in series to share their adjacent diffusion layer regions, and one end thereof is connected to a dummy transistor DT2 and the selection transistor STD2 on the bit line side. The other end is connected to the dummy transistor DT2 and the selection transistor STS2 on the source line side. The selection transistors STD2 and STS2, and a plurality of dummy transistors DT2 and the memory cell transistor MT2 sandwiched therebetween configure memory strings MS3 and MS4.

As described above, here, for ease of understanding and description, a configuration in which the number of memory mats is two comprised of MAT1 and MAT2, each of the memory mats includes two memory strings MS (MS1 and MS2, and MS3 and MS4), and the memory mat MAT2 is stacked over the memory mat MAT1 is illustrated. In practice, there are a plurality of memory strings MS and a plurality of memory mats MAT in a memory device.

The gate electrodes of the selection transistors STD1 are connected to a control line SGD1. The control line SGD1 is integrally configured with the selection gate electrode SGD1 as will be described later. The gate electrodes of the selection transistors STS1 are connected to a control line SGS1. The control line SGS1 is integrally configured with the selection gate electrode SGS1 as will be described later. The gate electrodes (a memory gate) of the memory cell transistors MT1 are connected to the word lines WL1. Agate electrode of the dummy transistor DT1 is connected to a dummy word line DWL1. The word lines WL1 are integrally configured with the memory gate MG1 which will described later.

The respective gate electrodes of the selection transistors STD2 are connected to a control line SGD2. The control line SGD2 is integrally configured with the selection gate electrode SGD2 as will be described later. The gate electrodes of the selection transistors STS2 are connected to a control line SGS2. The control line SGS2 is integrally configured with the selection gate electrode SGS2 as will be described later. The gate electrodes (a memory gate) of the memory cell transistors MT2 are connected to the word lines WL2. A gate electrode of the dummy transistor DT1 is connected to a dummy word line DWL2. The word lines WL2 are integrally configured with the memory gate MG2 which will be described later.

One of the diffusion layer regions of the selection transistors STD1 and STD2 of the memory strings MS1 and MS3 is connected to a bit line BL1. One of the diffusion layer regions of the selection transistors STD1 and STD2 of the memory strings MS2 and MS4 is connected to a bit line BL2. One of the diffusion layer regions of the selection transistors STS1 and STS2 of the memory strings MS1, MS2, MS3, and MS4 is connected to the source line SL.

The control lines SGD1 and SGD2, the word lines WL1 and WL2, the control lines SGS1 and SGS2, and the source line SL cross under the bit lines BL1 and BL2. The bit lines BL1 and BL2 are connected to a sense amplifier (not illustrated). The respective gate electrodes of a plurality of memory cell transistors MT1 and MT2 disposed in the row (Y) direction are electrically connected by the word lines WL1 and WL2.

The gate electrodes of the selection transistors STD1 of the memory strings MS1 and MS2 on the connection side with the bit lines BL1 and BL2 are electrically connected by the control line SGD1. The gate electrodes of the selection transistors STS1 on the connection side with the source line SL are electrically connected by control line SGS1.

The gate electrodes of the selection transistors STD2 of the memory strings MS3 and MS4 on the connection side with the bit lines BL1 and BL2 are electrically connected by the control line SGD2. The gate electrodes of the selection transistors STS2 on the connection side with the source line SL are electrically connected by the control line SGS2.

The sources of the selection transistors STS1 and STS2 of the memory strings MS1, MS2, MS3, and MS4 are connected to the source line SL through the contact plug 132 (a source line contact LI) in common.

Here, a bias condition when the simple stacked NAND flash memory device 100 performs data erasing will be described. As illustrated in FIG. 2, the bit line BL, the source line SL, and the control lines SGD and SGS are floated. 0 V is applied to the word line WL. Vdwl is applied to the dummy word line DWL. An erasing voltage Vera is applied to the semiconductor substrate 10 of the MAT1. The Vera applied to the semiconductor substrate 10 is applied to one (the connection side with the source line SL) of the diffusion layer regions of the selection transistors STS of the MAT2, and to one (the connection side with the bit line BL) of the diffusion layer regions of the selection transistors STD through the contact plugs 128 and 132 of FIG. 1.

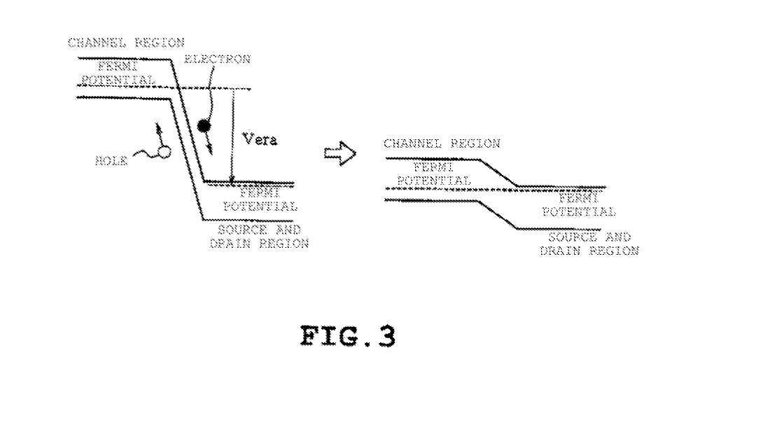

FIG. 3 schematically illustrates a potential applied to a channel region (the channel polysilicon layer 124) directly below the gate at an end of the diffusion layer region (the diffusion layer region 114b, and the defect layer region 140) of the selection transistors STD2 and STS2 in the bias condition described above. The Vera is applied to the diffusion layer region, and a potential difference with respect to the channel region occurs. The potential difference is a reverse bias between the diffusion layer region and the channel region, and thus a depletion layer is formed. Due to a high electric field in the depletion layer, an interband tunnelling current is generated. Accordingly, an electron-hole pair (an electron-hole pair) is generated, and thus the electron moves toward the diffusion layer region, and the hole moves toward the channel region. The hole(s) moving toward the channel region is accumulated in a channel portion below the memory gate MG2 of the memory strings MS3 and MS4, and the potential of the channel portion is raised. Accordingly, the channel portion increases to the erasing voltage Vera, and the hole moves into the lower electrode 106b (the accumulation electrode) through the insulating film 104b (the tunnel insulating film) to be combined with an electron, and thus it is possible to perform data erasing. Here, when it takes time to raise the potential as described above, an erasing delay time results, and thus an erase operation is delayed.

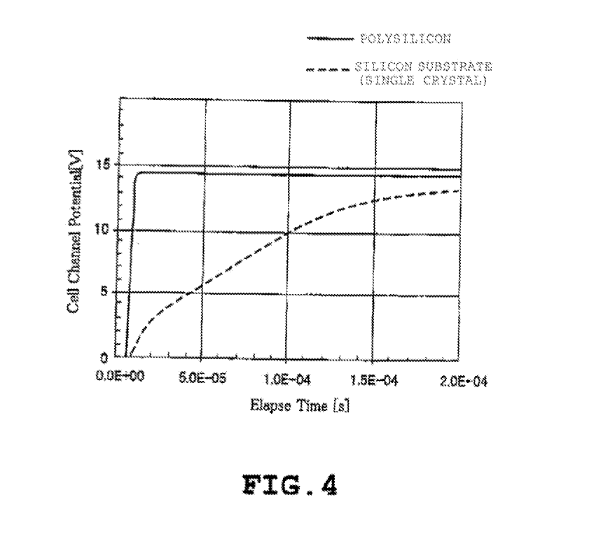

FIG. 4 illustrates a result of a simulation with respect to a change in a potential when single crystal silicon is used for the channel portion and the diffusion layer region, and when polysilicon is used for the channel portion and the diffusion layer region.

FIG. 4 illustrates a change in a channel potential after the erasing voltage Vera is applied to a diffusion layer region 114. In FIG. 4, a horizontal axis is an elapsed time (sec), and a vertical axis is a potential (V) of the channel portion. The polysilicon is formed by forming multiple crystal grains (grains) of silicon, such that there are crystal grain boundaries (Grain boundary) at the boundary between adjacent crystal grains. In addition, a crystal defect may be in the grain. In the crystal grain boundary or the crystal defect, a dangling bond is formed to serve as a generation and recombination center for electron-hole pairs (a generation-recombination center). In addition, a carbon atom which is introduced into the silicon also serves as the generation and recombination center. Since the generation and recombination center increases by introducing germanium and carbon, generation efficiency of the electron-hole pair increases.

On the other hand, in the single crystal silicon, or silicon of which crystallinity is improved by laser annealing or the like, the number and or size of the crystal grain boundaries, and the number of crystal defects decreases, and thus the number of electron hole pair generation and recombination locations decreases. Accordingly, generation efficiency of electron-hole pairs decreases.

In FIG. 4, line A illustrated by a broken line indicates the potential of the channel region when single crystal silicon having excellent high crystalline state (large grain size or continuous single crystal with few defects) is used as the channel polysilicon layer 124, and a line B illustrated by a solid line indicates the potential of the channel region when polysilicon is used as the channel polysilicon layer 124. In this simulation, the polysilicon is the defect layer region 140 into which a defect is introduced.

As illustrated by line A, when single crystal silicon is used for the channel polysilicon layer 124, the generation of the electron-hole pairs decreases. For this reason, the channel potential rises slowly, and thus it takes a at least 200 μsec to raise the potential to 14 V.

In contrast, as illustrated by line B, when polysilicon is used for the channel polysilicon layer 124, that is, when polysilicon having a plurality of grain boundaries and/or crystal defects, where the number of generation and recombination centers (the electron-hole pair generation-recombination centers) are increased is used for the channel polysilicon layer 124, the generation of electron-hole pairs increases. For this reason, the channel potential is raised to 14V at a high speed of approximately 10 μsec. When polysilicon is used for the channel polysilicon layer 124, that is, when the defect layer region 140 is formed, it is understood that the channel potential is raised in a much shorter time as compared to the erasing time of the simple stacked NAND flash memory device 100.

According to the simulation result described above, it is understood that, when the silicon into which a plurality of generation and recombination centers is introduced is used, the generation of electron-hole pairs increases, and when the erasing voltage Vera is applied to the diffusion layer region of the selection gate electrode SG, the channel potential is rapidly raised and the erasing time is considerably shortened. That is, it is understood that, when the defect layer region 140 is disposed in the diffusion layer region of the selection gate electrode SG on a side thereof which is not adjacent to the memory gate MG, the channel potential is raised in a short time, and thus the erase operation occurs quickly.

As described above, according to this embodiment, the defect layer region 140 is disposed on one of the diffusion layer regions (source or drain) of the selection transistors STD and STS on the side thereof which is not adjacent to the memory gates MG. In addition, to form the defect layer region 140, germanium and carbon are introduced into the diffusion layer adjacent the non-memory gate MG side of the selection transistors STD and STS by an ion implantation method. In the defect layer region 140, the polysilicon grain diameter (a crystal size) of the silicon is further reduced by introducing germanium, and thus there are plenty of crystal grain boundaries (grain boundaries). In addition, defects are intentionally introduced into the polysilicon by the ion implantation of germanium. In addition, carbon is introduced into the defect layer region 140. Due to the crystal grain boundary, the defect in the grain, and introduced carbon, a multitude of electron-hole pair generation and recombination centers are introduced into the defect layer region 140. Due to the generation and recombination centers, generation efficiency of electron-hole pairs increases in the defect layer region 140. Accordingly, when a high electric field is applied to the defect layer region 140, the generation of the electron-hole pairs increases in a short time. Accordingly, multiple holes are accumulated in the channel portion of the memory string MS in a short time, and thus the potential of the channel portion is rapidly raised, and the erasing time to erase the memory cells is shortened.

If the defect layer region 140 is formed in the entire region of the channel portion of the memory string MS, electron mobility decreases in the defect layer region 140, and it is not possible to allow a sufficient current to flow to the memory string MS, and thus the reading speed of the memory cells decreases. According to this embodiment, the defect layer region 140 is not formed in the channel region of the lower portion of the memory gate MG, and instead a channel polysilicon layer 124 having an excellent crystalline state (that is, the number of crystal defects is less, the grain diameter of the polysilicon grains are greater, and the grain boundaries are fewer) is formed. Germanium or carbon is not introduced into the channel polysilicon layer 124. In the channel polysilicon layer 124, the number of electron-hole pair generation and recombination centers is fewer than in the defect layer region 140. Accordingly, the channel polysilicon layer 124 has high electron mobility, and it is possible to allow a sufficient current to flow to the memory string MS.

(Manufacturing Method of First Embodiment)

Next, a manufacturing method of a simple stacked NAND type flash memory device according to the first embodiment will be described. FIG. 1 and FIGS. 5 to 10 are examples of a longitudinal sectional view illustrating the result of a manufacturing method for a simple stacked NAND flash memory device 100 according to the first embodiment.

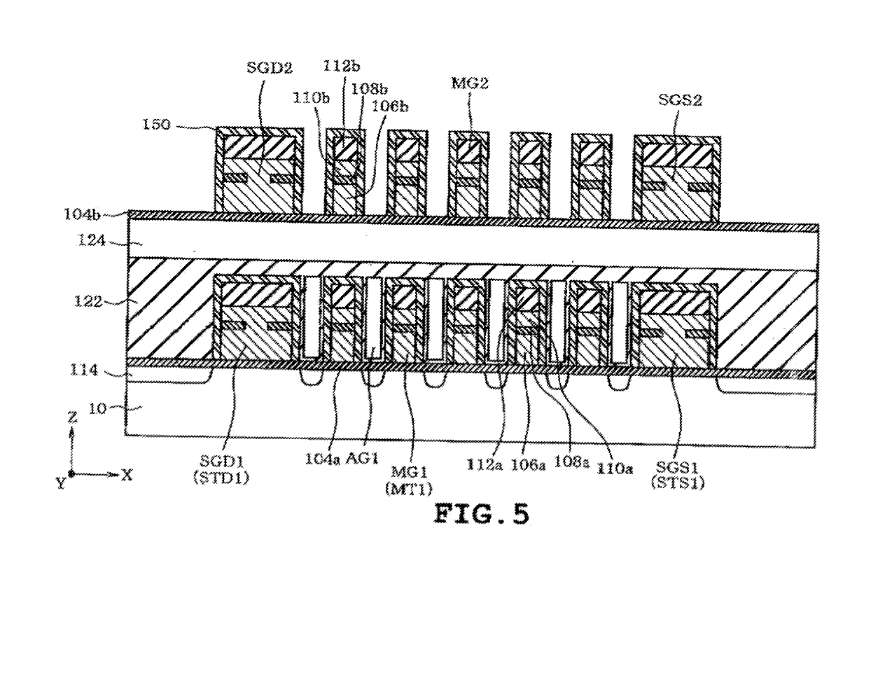

First, as illustrated in FIG. 5, the selection gate electrodes SGD1 and SGS1 and the plurality of memory gates MG1 are formed on the semiconductor substrate 10, and an upper portion thereof is covered with the interlayer insulating film 122, and then the upper surface is flattened (planarized such as by chemical mechanical polishing thereof). As the semiconductor substrate 10, for example, it is possible to use a silicon substrate.

Next, the channel polysilicon layer 124 is formed on the interlayer insulating film 122, and then the insulating film 104b is formed thereover, and on an upper portion thereof, the selection gate electrode SGD2, control line SGS2 and the memory gates MG2 are formed. Subsequently, a thin insulating film 150 is formed on the upper surfaces and side surfaces of the selection gate electrode SGD2, control line SGS2 and the memory gates MG2. As the channel polysilicon layer 124, for example, a layer in which a polysilicon film is formed by using a Chemical Vapor Deposition (CVD) method, for example, wherein it is possible to increase the crystallinity of the silicon by a laser annealing method.

In addition, instead of the deposition of a polysilicon CVD film as described above, an amorphous silicon film may be formed, and the amorphous film is heat treatment using a furnace or a Rapid Thermal Annealing (RTA) method, and the crystallinity of the silicon may be increased, i.e., the amorphous layer may be modified by heat treatment into a polysilicon (polycrystalline silicon) layer. As the insulating film 150, for example, it is possible to use a silicon oxide film formed by a CVD method.

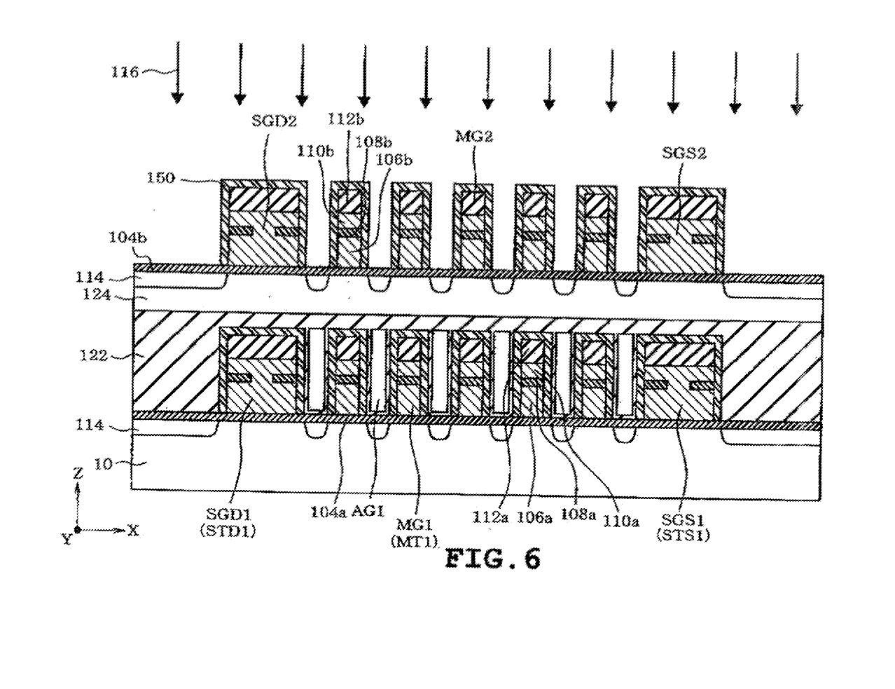

Next, as illustrated in FIG. 6, dopants 116 are implanted into the channel polysilicon layer 124 by using an ion implantation method to form the source and drain regions of the selection and memory cell transistors. As the dopant 116, for example, it is possible to an n type dopant such as boron (B) and/or phosphorus (P). Accordingly, the diffusion layer region 114 is able to be formed. As the dopant, arsenic (As) as a p type dopant may be implanted.

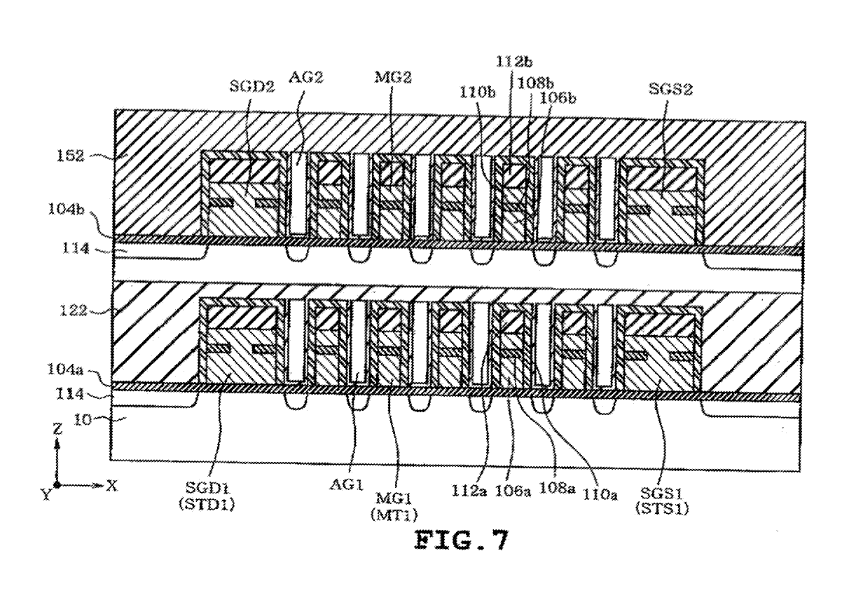

Subsequently, as illustrated in FIG. 7, an insulating film 152 is formed. As the insulating film 152, it is possible to use a silicon oxide film formed under poor step coverage conditions. It is possible to form the insulating film 152, for example, by using a plasma CVD method. When the insulating film 152 is formed having poor step coverage, a narrow space between the memory gates MG2, and between the selection gate electrode SG2 and the memory gate MG2 is not filled, and an air gap AG2 is formed.

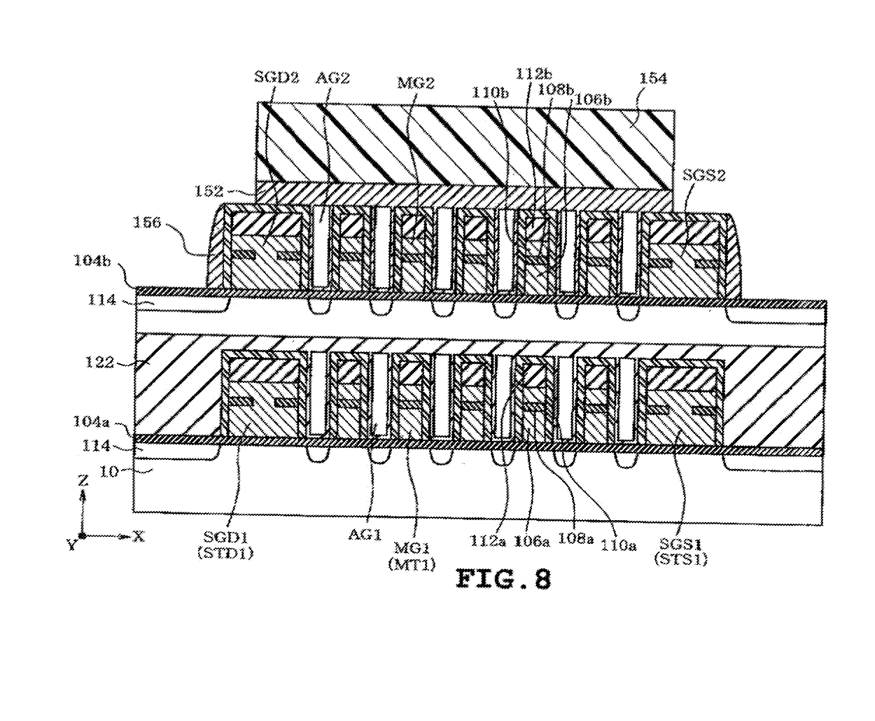

Next a resist layer 154 is formed on the insulating film 152 covering the memory gates MG2 and at least portions of the selection gate electrode SGD2 and control line SGS2 by using a photolithographic method, and etching is performed by a Reactive Ion Etching (RIE) method using the cover resist 154 as a mask. Accordingly, a side wall insulating film 156 as illustrated in FIG. 8 is formed on a side wall of the selection gate electrodes SG2 (SGD2, SGS2).

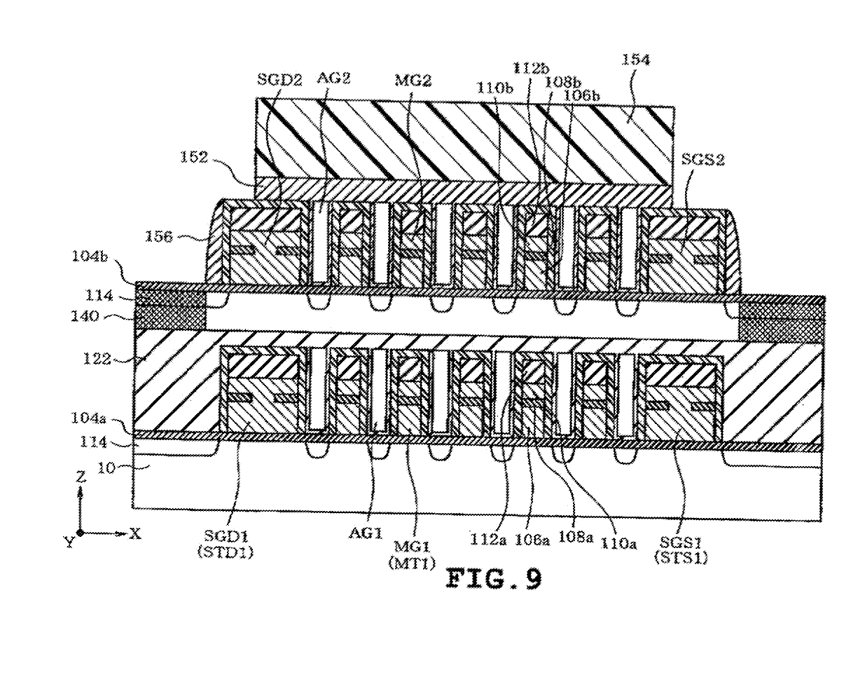

Next, as illustrated in FIG. 9, germanium (Ge) or carbon (C) is implanted into portions of the channel polysilicon layer 124 not covered by the selection gate electrodes SG2 (SGD2, SGS2) and memory gates MG2, as well as the side wall insulating film, by using an ion implantation method. Both germanium and carbon may be implanted into the portion of the polysilicon layer. In the ion implantation step, the resist 154, the side wall insulating film 156 and selection gate electrodes SG serve as a mask, and germanium and carbon are implanted into the channel polysilicon layer 124 adjacent the side wall insulating film 156. The portion of the polysilicon layer 124 into which germanium and carbon are implanted is the defect layer region 140. By implanting the germanium and carbon, crystal defects and thus electron-hole pair generation and recombination centers are introduced to form the defect layer region 140 as shown schematically in FIG. 9. Furthermore, it is preferable that a dose amount be greater than or equal to 10²⁰ cubic centimeters so as to of a percentage order of magnitude with respect to density of silicon atoms in the defect layer region 140.

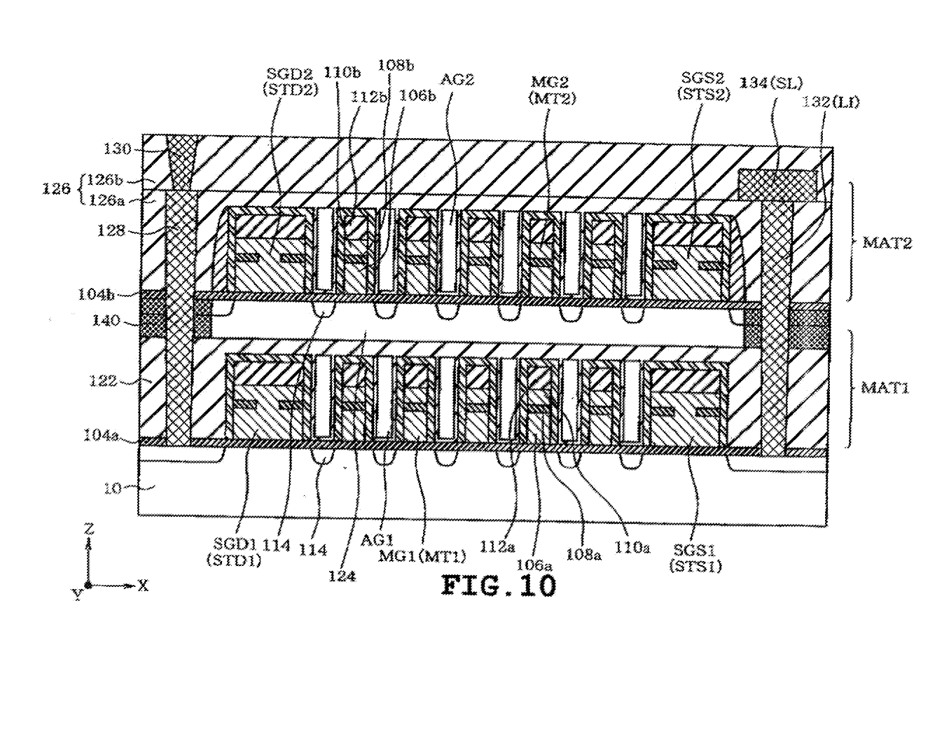

Next, referring to FIG. 10, the resist 154 is removed, and an interlayer insulating film 126a is formed. As the interlayer insulating film 126a, for example, it is possible to use a silicon oxide film formed by a CVD method. Subsequently, a hole is formed from an upper surface of the interlayer insulating film 126a to the surface of the semiconductor substrate 10 through the interlayer insulating film 126a, the channel polysilicon layer 124 (the defect layer region 140), and the interlayer insulating film 122, and a conductive film is formed in the hole, and thus the contact plugs 132 and 128 are formed. The wiring 134 is formed on the contact plug 132. The wiring 134 is the source line SL. As the contact plug 132, for example, a stacked structure of titanium nitride (TiN) and tungsten (W) may be used, where the TiN lines the walls of the holes and the W is formed thereover. Likewise, the wiring 134 may be formed of tungsten (W).

Subsequently, an interlayer insulating film 126b is formed, and the electrode 130 is formed from the surface of the interlayer insulating film 126b to an upper surface of the contact plug 128. As the interlayer insulating film 126b, for example, a silicon oxide film formed by a CVD method may be used. It is possible to form the electrode 130, for example, by using tungsten.

Subsequently, as is illustrated in FIG. 1, the wiring 136 is formed on the interlayer insulating film 126. The wiring 136 is in contact with an upper surface of the electrode 130. It is possible to form the wiring 136, for example, by using tungsten. The wiring 136 is the bit line BL. All of the interlayer insulating films 126a and 126b, and the insulating film 152 are silicon oxide films, and thus a boundary of the insulating film 152 is not shown but integrally illustrated in FIG. 10. In addition, the interlayer insulating films 126a and 126b are integrally illustrated as the interlayer insulating film 126.

According to a process described above, it is possible to make the simple stacked NAND flash memory device 100 according to the first embodiment. In the simple stacked NAND flash memory device 100 according to the first embodiment, the defect layer region 140 is formed by performing the ion implantation of germanium and carbon with respect to a silicon layer which is formed to have an excellent crystalline state using laser annealing or the like. A multitude of crystal defects and a multitude of electron hole-pair generation and recombination centers are created into the defect layer region 140 by the implanting step. When a high electric field is applied to the defect layer region 140, the generation of a large quantity of electron-hole pairs occurs in a short time. Accordingly, plenty large quantity of holes is accumulated in the channel portion of the memory strings MS3 and MS4 in a short time, and thus the potential of the channel portion is rapidly raised, and the erase operation occurs more quickly.

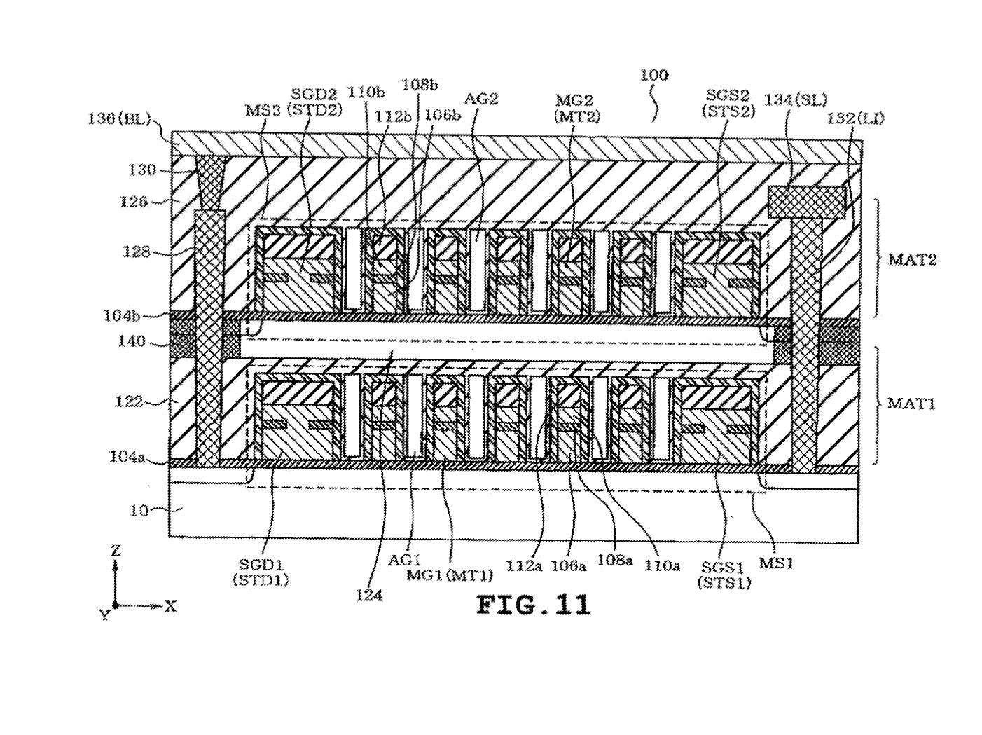

In addition, in an example described above, a case where the diffusion layer regions 114 are disposed on the both sides of the memory gates MG is illustrated, but as illustrated in FIG. 11, a simple stacked NAND flash memory device 100 which is formed without disposing the diffusion layer region 114 may be applied to the semiconductor memory device. That is, a so-called fringe cell type stacked NAND flash memory device 100 which is operated by forming an inversion layer on the channel polysilicon layer 124 by a fringe electric field from the memory gate MG without requiring the diffusion layer region 114 may be applied to the semiconductor memory device.

### Second Embodiment

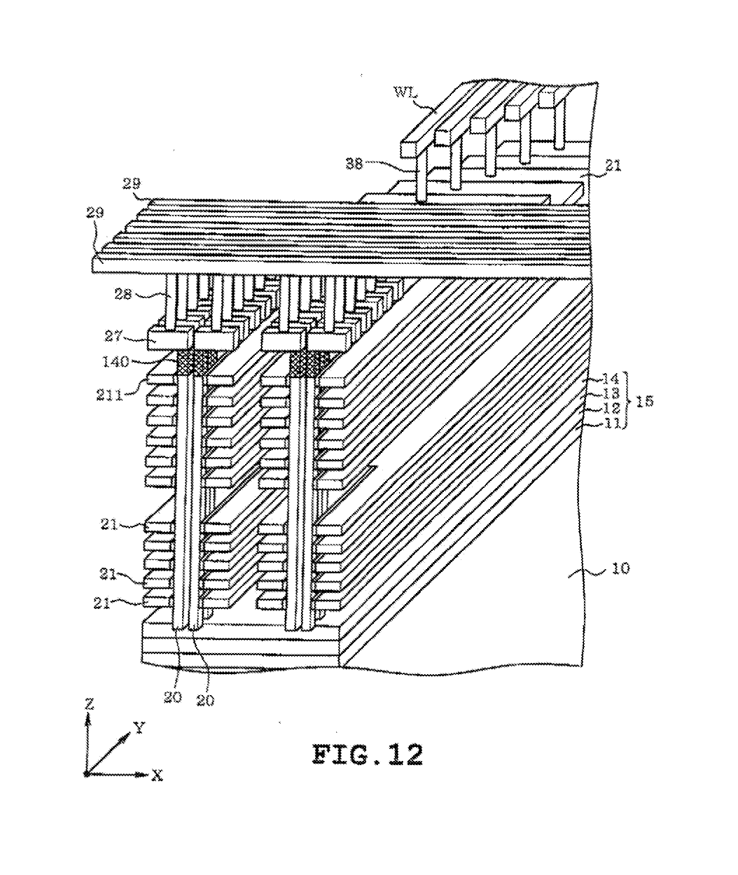

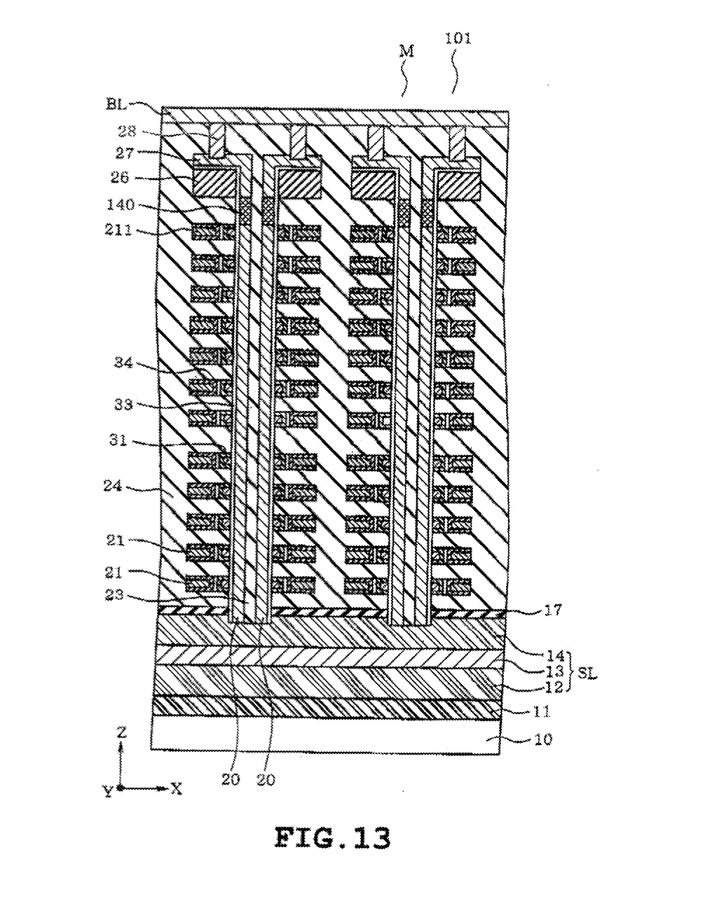

A three-dimensional NAND flash memory device 101 according to a second embodiment will be described with reference to FIG. 12 and FIG. 13. Furthermore, the same reference numerals are applied to the same elements as described above, and the detailed description thereof will be suitably omitted.

FIG. 12 is an example of a perspective view illustrating a three-dimensional NAND flash memory device 101 according to the second embodiment. In FIG. 12, in order to facilitate understanding, the interlayer insulating film or the like is omitted. FIG. 13 is an example of a longitudinal sectional view illustrating the three-dimensional NAND flash memory device 101 according to the second embodiment.

As illustrated in FIG. 12 and FIG. 13, in the three-dimensional NAND flash memory device 101 according to this embodiment, a memory cell region M is disposed on a semiconductor substrate 10. As the semiconductor substrate 10, for example, it is possible to use a silicon substrate. In the memory cell region M, for example, an insulating film 11, a conductive layer 12, a wiring layer 13, and a conductive layer 14 are formed in that order on the silicon substrate 10. As the insulating film 11, for example, it is possible to use a silicon oxide film. As the conductive film 12, for example, it is possible to use polysilicon. As the wiring layer 13, for example, it is possible to use tungsten. As the conductive layer 14, for example, it is possible to use polysilicon. A source line SL is formed by the conductive layer 12, the wiring layer 13, and the conductive layer 14. An insulating film 17 is formed on the source line SL. As the insulating film 17, for example, it is possible to use a silicon oxide film.

A plurality of silicon pillars 20 extend in a vertical direction with respect to the semiconductor substrate 10, that is, in the Z direction in the drawing, are disposed on the source line SL. The silicon pillars 20 (a columnar semiconductor layer), for example, have a shape such as a columnar shape, and a prismatic shape. As the silicon pillar 20, for example, it is possible to use polysilicon. The silicon pillar 20 passes through the insulating film 17, and a lower end thereof is in contact with the source line SL. The plurality of silicon pillars 20 are connected to the source line SL in common.

A plurality of control gate electrode films 21 are disposed on sides of the silicon pillar 20 and separated from each other in the Z direction in the drawing. As the control gate electrode film 21, for example, it is possible to use tungsten. The control gate electrode films 21 extend in the Y direction in the drawing as shown in FIG. 12.

An insulating film 23 is disposed between the adjacent silicon pillars 20. An interlayer insulating film 24 is surrounds the control gate electrode films 21 and the silicon pillars 20. As the interlayer insulating film 24, for example, it is possible to use a silicon oxide film. The plurality of control gate electrode films 21, the insulating film 23, and the interlayer insulating film 24 form a stacked body in which a plurality of memory levels are stacked, and on an upper portion thereof, a hard mask 26 is disposed.

The silicon pillar 20 extends through, and lies over, the hard mask 26, and to become integrated with wiring 27 extending in the X direction in the drawing. A conductive via 28 is disposed on the wiring 27, and a bit line BL extending in the X direction in the drawing is disposed on the via 28. The bit line BL is connected to the wiring 27 through the vias 28. In an end portion of the stacked body in the Y direction in the drawing, the control gate electrode films 21 are formed in steps, and in the step-like end portion, a via 38 is connected onto the respective control gate electrode films 21. A word line WL extending in the Y direction in the drawing is connected onto the via 38. A defect layer region 140 is formed in a position corresponding to a lower end position of the hard mask 26 from an upper end position of a control gate electrode film 211 in the silicon pillar 20 at an uppermost level of the memory cells, i.e., between a control gate electrode film layer 211 and the connection of the pillar to the wiring 27 extending in the X direction. The control gate electrode film 211 on the uppermost stage functions as a selection gate electrode SGD. Accordingly, the configuration described above indicates that the defect layer region 140 is formed in a diffusion layer region of a selection transistor STD formed by the selection gate electrode SGD on a connection side with the bit line BL in the silicon pillar 20.

A floating gate electrode film 31 is disposed between the silicon pillar 20 and the control gate electrode films 21. The floating gate electrode films 31 are disposed at an intersection point between the silicon pillar 20 and the control gate electrode films 21. A tunnel insulating film 33 is disposed between the silicon pillar 20 and the floating gate electrode film 31. A block insulating film 34 is disposed between the floating gate electrode film 31 and the control gate electrode film 21. The block insulating film 34, for example, is a multi-layered film including a silicon nitride layer, a silicon oxide layer, and a silicon nitride layer. The silicon nitride layer surrounds the floating gate electrode film 31. The silicon oxide layer and the silicon nitride layer surround the control gate electrode film 21.

Next, a manufacturing method of a three-dimensional NAND flash memory device 101 according to the second embodiment will be described.

FIG. 13 to FIG. 22 are examples of a longitudinal sectional view illustrating the results of steps in a manufacturing method of a three-dimensional NAND flash memory device 101 according to this embodiment, and illustrate a longitudinal sectional view of the memory cell region M in a process sequence.

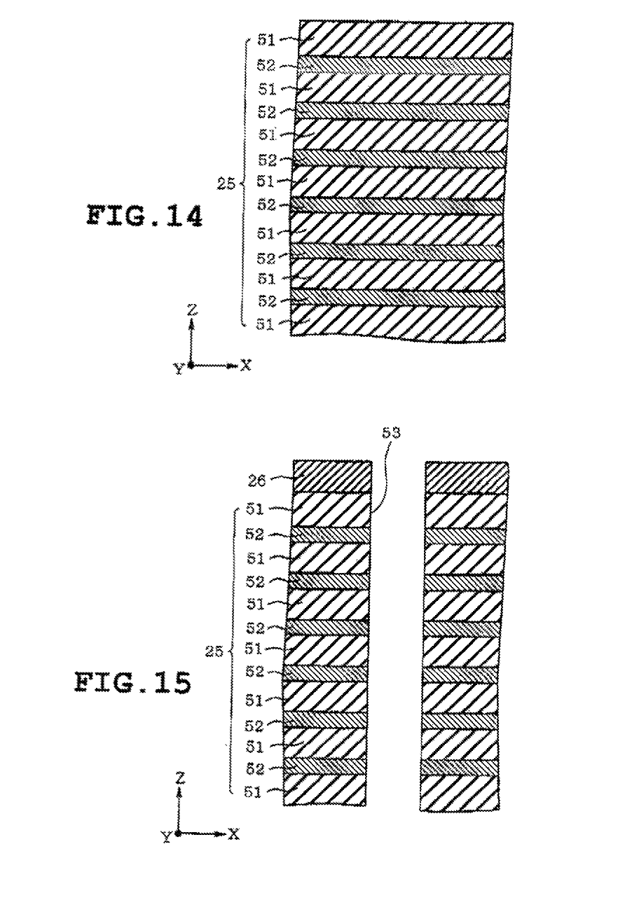

First, as illustrated in FIG. 14, a stacked body 25 is formed by alternately depositing a silicon oxide film 51 and a silicon nitride film 52 on one another. It is possible to form the silicon oxide film 51 and the silicon nitride film 52, for example, by a CVD method.

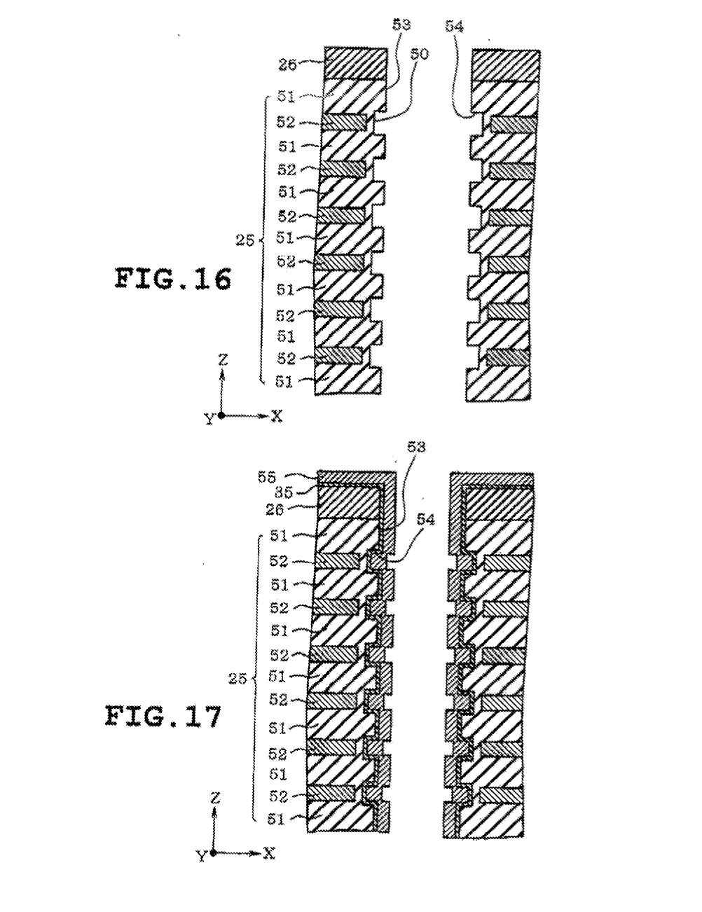

Next, for example, a hard mask 26 layer of silicon nitride is formed on the stacked body 25. Then, the hard mask 26 is patterned by using a photolithographic method, and an etching is performed with respect to the stacked body 25 by an RIE method according to an anisotropic condition using the patterned hard mask 26 as a mask. Accordingly, a trench 53 passing through the stacked body 25 is formed in the stacked body 25 as illustrated in FIG. 15. The trench 53 extends in the Y direction in the drawing.

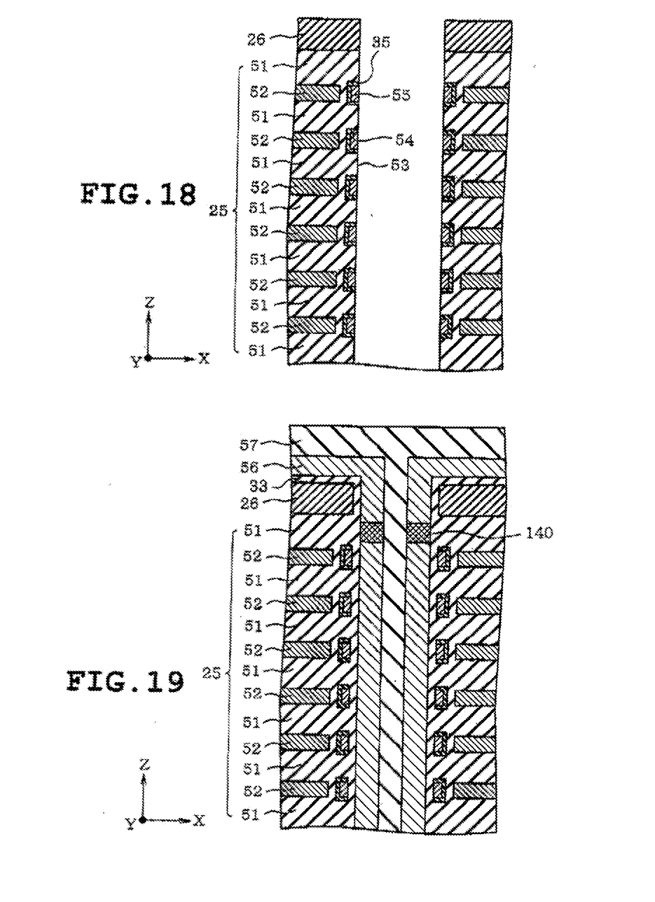

Next, for example, the silicon nitride film 52 is retracted (inset) in a traverse direction (in the drawing, the X direction) by performing a wet etching, and a recess thereof, with respect to the silicon oxide film 51 is formed. Accordingly, a portion of the silicon nitride film 52 is retracted inwardly of an inner surface of the trench 53. Next, for example, an oxidation treatment is performed by a plasma oxidation method. Accordingly, a concave portion 54 (a recess) extending in the traverse direction (in the drawing, the Y direction) is formed as a surface of the silicon nitride film 52 exposed to the concave portion 54 is oxidized, and a silicon oxide layer 50 is formed thereover as illustrated in FIG. 16.

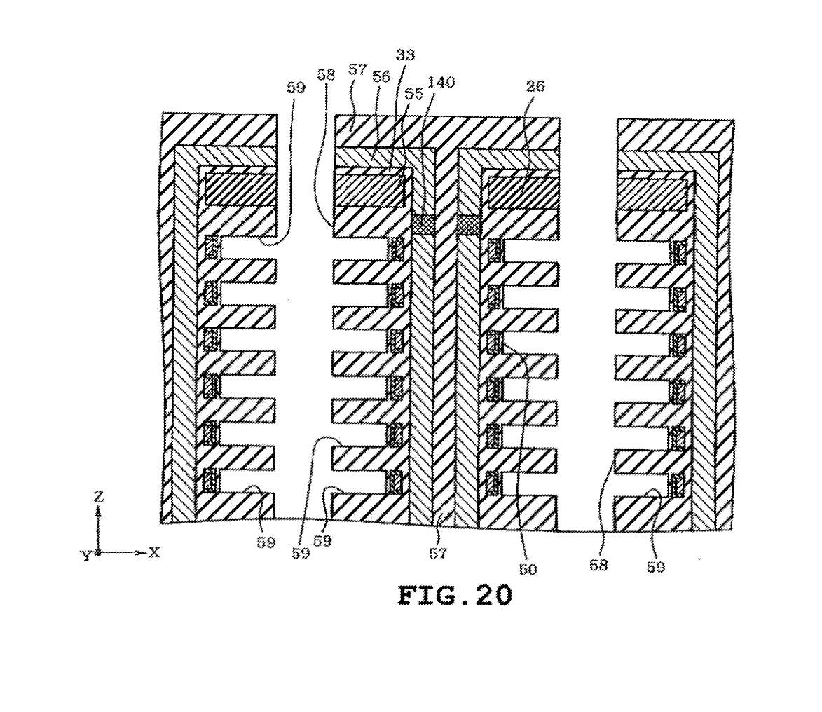

Next a silicon nitride layer 35, and a polysilicon film 55 are sequentially formed on the entire surface, resulting the structure illustrated in FIG. 17. It is possible to form the silicon nitride layer 35 and the polysilicon film 55, for example, by a CVD method, and they are conformally formed on the inner surface of the trench 53 including the inside of the concave portion 54.

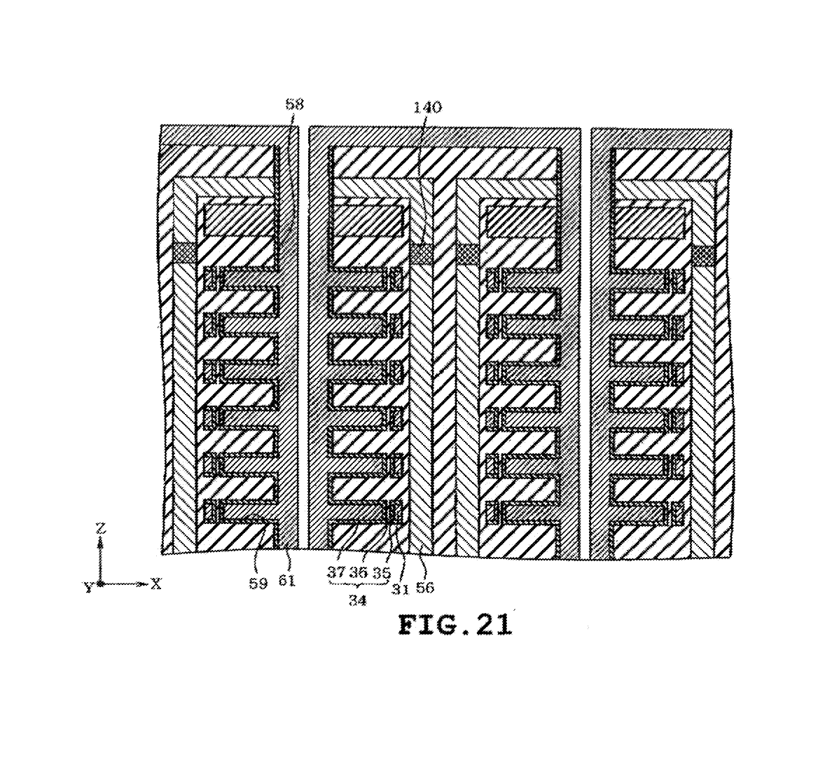

Next, an anisotropic etching such as RIE is performed along the trench 53, and thus the polysilicon film 55 and the silicon nitride layer 35 are selectively removed, and the portion of the polysilicon film 55 extending inwardly of the concave portion 54 and in the adjacent concave portions 54 in the Z direction are isolated from each other as illustrated in FIG. 18. Similarly, the silicon nitride layers 35 remaining in the adjacent concave portions 54 in the Z direction are separated from each other.

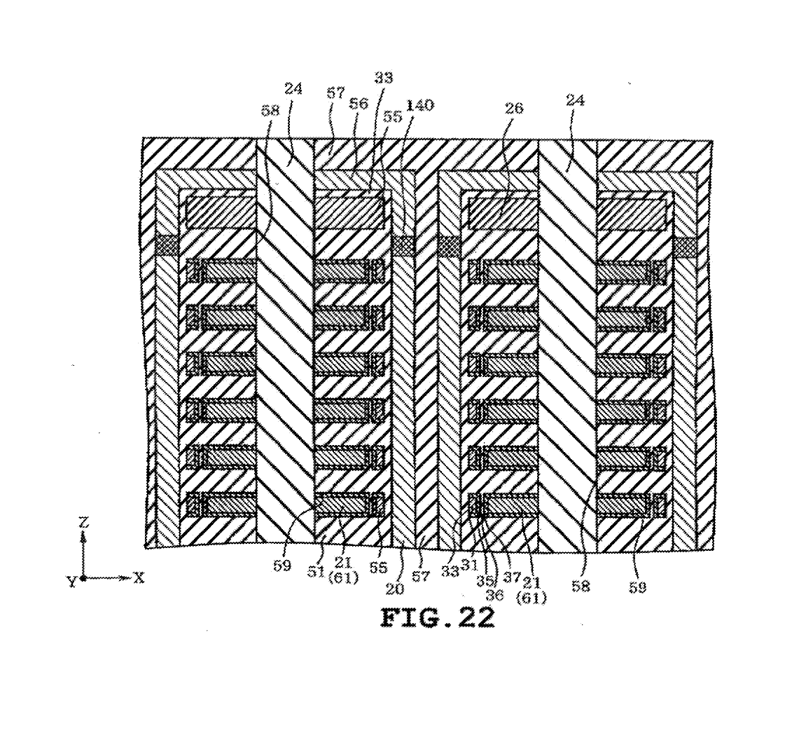

Next, the tunnel insulating film 33, a polysilicon film 56, and an insulating film 57 are formed. Subsequently, by using an ion implantation method, incident energy (an acceleration voltage) of the ions are adjusted such that an implant depth range of germanium and carbon ions is selected to implant the germanium and carbon ions into the silicon pillars 20 at a location corresponding to the uppermost portion of the silicon oxide film 51, that is, the implanted region is below the lower surface of the hard mask 26 and above the upper surface of the silicon nitride film 52 on the uppermost portion, As is shown in FIG. 19. Accordingly, germanium and carbon are implanted into the polysilicon film 56 positioned at the height of the silicon oxide film 51 above the uppermost silicon nitride 52 film, and the defect layer region 140 is thus formed in the silicon pillars 20. Any one of germanium and/or carbon may be implanted. Furthermore, an upper portion of a region for forming the defect layer region 140 is covered with a resist provided with an opening by using a lithographic method, and thus ion implantation may be selectively performed only in the intended region for forming the defect layer region 140. As such, the resist layer 26 provides a self aligned implant mask layer.

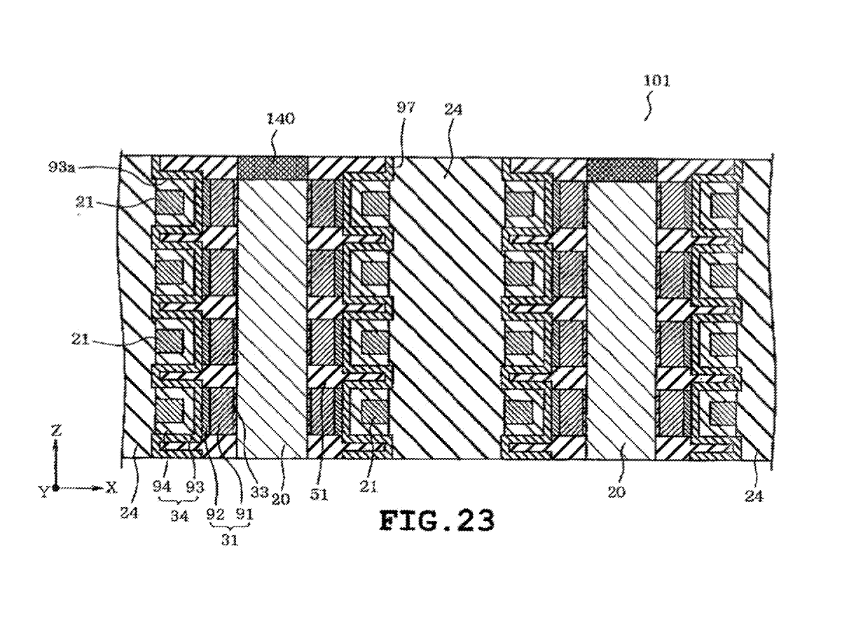

Next, a trench 58 extending in the Y direction is formed between adjacent trenches 53 previously formed in the stacked body 25, as illustrated in FIG. 20. Accordingly, trenches 53 and trenches 58 are alternately disposed along the X direction. By performing a wet etching using a hot phosphoric acid, the silicon nitride film 52 exposed by the trench 58 may be removed, resulting in recesses in the silicon oxide layer 51 along the depth of the trench 58. The recess depth is stopped by the presence of silicon oxide of the silicon oxide layer 50, resulting in recesses 59 where the silicon nitride film 52 was removed and the recesses 59 extending in the Y direction are thus formed in an inner surface of the trench 58. At this time, the silicon nitride layer 35 is enclosed by the silicon oxide layer 50, and thus is not damaged or removed.

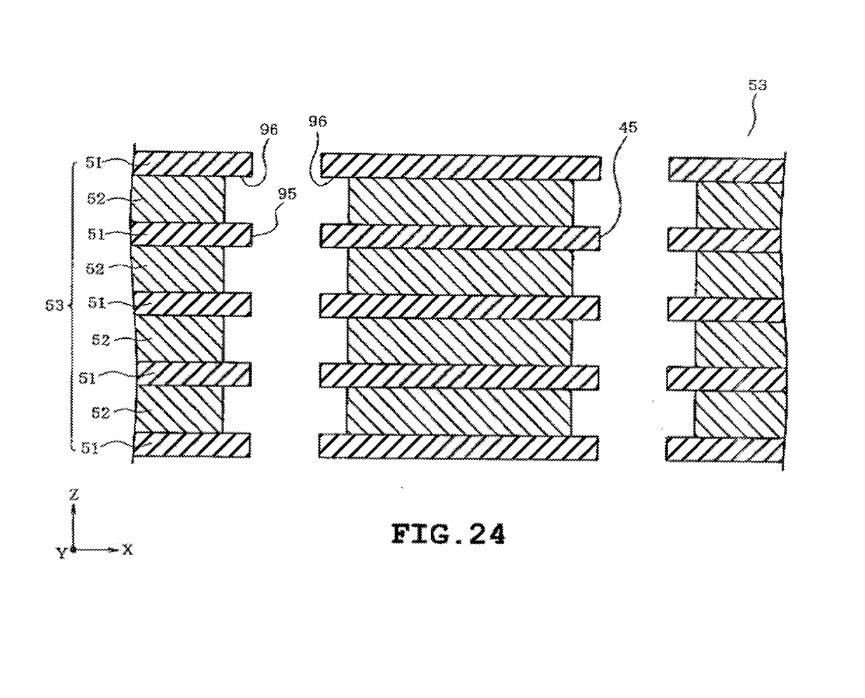

Next, as illustrated in FIG. 21, the silicon oxide layer 50 exposed to the recesses 59 is removed, and the silicon nitride layer 35 is exposed in the recesses 59. Next, a silicon oxide layer 36 and a silicon nitride layer 37 are formed on the inner surface of the trench 58 including the recesses 59. As a result, the block insulating film 34 is formed by the silicon nitride layer 35, and silicon oxide layer 36, and the silicon nitride layer 37. Next, for example, a tungsten film 61 is formed on the entire surface of the trench 58 including the inside of the recesses 59 by a Chemical Vapor Deposition (CVD) method.

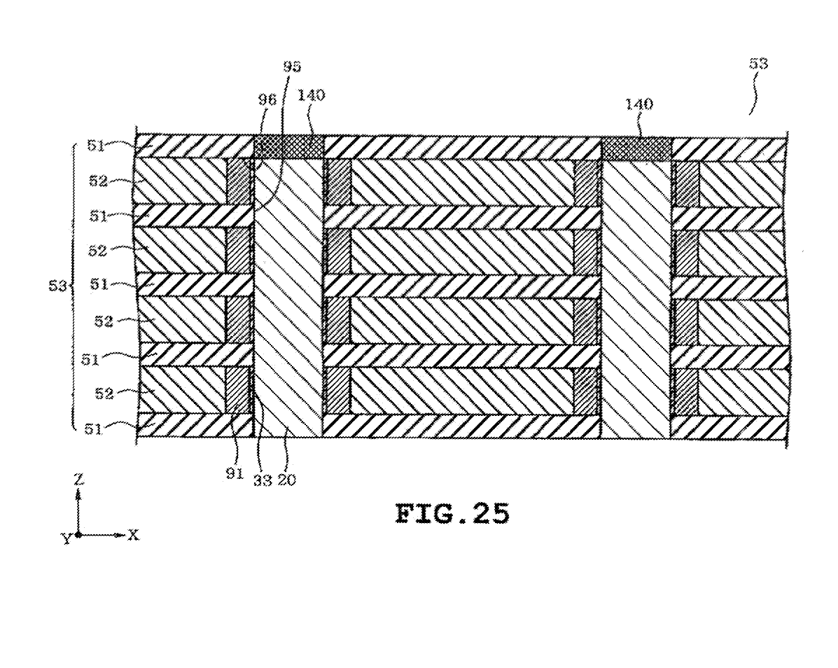

Next, the tungsten film 61 is selectively removed by performing an anisotropic etching such as an RIE method. Accordingly, the tungsten film 61 remains in the recesses 59, and are separated from each other in the Z direction by the intervening silicon oxide. As a result, the control gate electrode film 21 including the tungsten film 61 is formed in the concave portion 59. Subsequently, the interlayer insulating film 24 is embedded in the trench 58, and an upper surface thereof is flattened, with the resulting structure as illustrated in FIG. 22.

Referring to FIG. 13, the floating gate electrode film 31 is formed, and then the interlayer insulating film 24 is deposited on the entire surface, and subsequently, the via 28 and the bit line BL are formed. The control gate electrode film 211 of the uppermost portion is used as a selection gate electrode SG. Thus, the three-dimensional NAND flash memory device 101 according to this embodiment is formed.

As described above, according to the second embodiment, the defect layer region 140 is formed in the control gate electrode film 211 of the uppermost portion, that is, a side of the selection transistor STD opposite to the memory gate MG, that is, the diffusion layer region on the connection side with the bit line BL. A defect is introduced into the defect layer region 140 by introducing germanium and carbon, and a plurality of electron-hole pair generation and recombination centers is introduced into the defect layer region 140. Accordingly, when a reverse bias voltage is applied to the diffusion layer region, interband tunnelling easily occurs in a formed depletion layer. Accordingly, the same effect as in the first embodiment is obtained.

### Third Embodiment

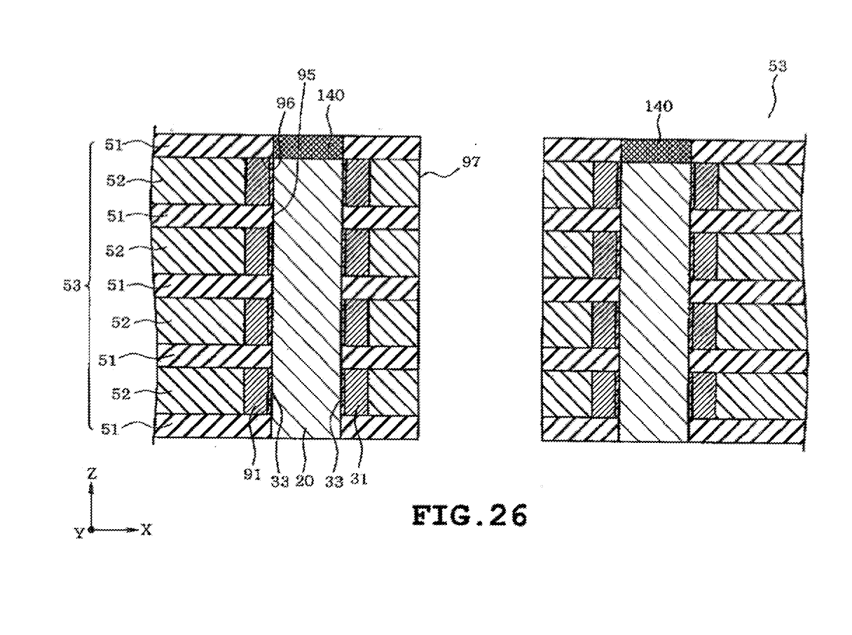

Next, a three-dimensional NAND flash memory device 101 according to a third embodiment will be described with reference to FIG. 23. FIG. 23 is an example of a longitudinal sectional view illustrating a structure of the three-dimensional NAND flash memory device 101 according to this embodiment. Furthermore, the same reference numerals are applied to the same elements as described above, and the detailed description thereof will be suitably omitted.

As illustrated in FIG. 23, in the three-dimensional NAND flash memory device 101, a plurality of silicon pillars 20 extend in the Z direction in the figure. A tunnel insulating film 33, a floating gate electrode film 31, and a block insulating film 34 are disposed to surround the silicon pillar 20. The floating gate electrode film 31 surrounds the silicon pillar 20.

In the Z direction in the drawing figure, a silicon oxide film 51 is disposed between the adjacent floating gate electrode films 31. The floating gate electrode film 31 includes a polysilicon layer 91 and a metal silicide layer 92 formed with one contacting the other in a side by side fashion. The metal silicide layer 92 may be formed of metal.

The block insulating film 34 includes a silicon oxide layer 93 and a high permittivity layer 94 which are formed with one contacting the other in a side by side fashion. As the high permittivity layer 94, for example, it is possible to use hafnium oxide (HfO), aluminum oxide (AlO), titanium nitride (TiN), tantalum nitride (TaN), or tantalum oxide (TaO). The silicon oxide layer 93 is continuously formed in the Z direction in the drawing, and is formed in the shape of a tube as a whole. The high permittivity layers 94 is disposed in a concave portion 93a in an outer surface of a cylinder formed by the silicon oxide layer 93, and is separated for each concave portion 93.

A plurality of control gate electrode films 21 are disposed in matrix along the X direction and the Z direction in the drawing. The control gate electrode film 21 is formed in the shape of a strip extending in the Y direction. The control gate electrode film 21 is a conductive film, and for example, it is possible to use a multi-layered film of a titanium nitride layer (TiN) and a tungsten layer (W), a multi-layered film of a tungsten nitride layer (WN) and a tungsten layer (W), a multi-layered film of a tantalum nitride layer (TaN) and a tungsten layer (W), or the like.

A structure which includes the silicon pillar 20, the tunnel insulating film 33, the floating gate electrode film 31, and the block insulating film 34 passes through the control gate electrode film 21. The control gate electrode film 21 is disposed in the concave portions 93a. The control gate electrode film 21 is surrounds the floating gate electrode film 31 as seen from the Z direction in the drawing. An interlayer insulating film 24 is formed to cover the entire structure including the silicon pillar 20, the tunnel insulating film 33, the floating gate electrode film 31, the block insulating film 34, and the control gate electrode film 21.

In an upper portion of the silicon pillar 20 in the Z direction in the drawing, a defect layer region 140 is formed in the pillar 20 above upper end portion of the control gate electrode film 21 and the floating gate electrode film 31 in an uppermost portion. The control gate electrode film 21 and the floating gate electrode film 31 in the uppermost portion of the pillars 20 function as a gate electrode (a selection gate electrode SG) of a selection transistor ST in a memory cell of the three-dimensional NAND flash memory device 101. The defect layer region 140 is disposed in a diffusion layer region on a connection side of a bit line BL of the selection transistor ST. The silicon pillar 20 and the defect layer region 140, for example, are formed of polysilicon. Crystallinity of the polysilicon is excellent in the silicon pillar 20, and a polysilicon grain diameter of the silicon pillar 20 is greater than a polysilicon grain diameter of the defect layer region 140. The polysilicon grain diameter of the defect layer region 140 is smaller than the polysilicon grain diameter of the silicon pillar 20. Germanium (Ge) or carbon (C) is introduced into the pillar 20 to form the defect layer region 140. A plurality of electron hole pair generation and recombination centers exist in the defect layer region 140 by introducing crystal defects and carbon and/or germanium.

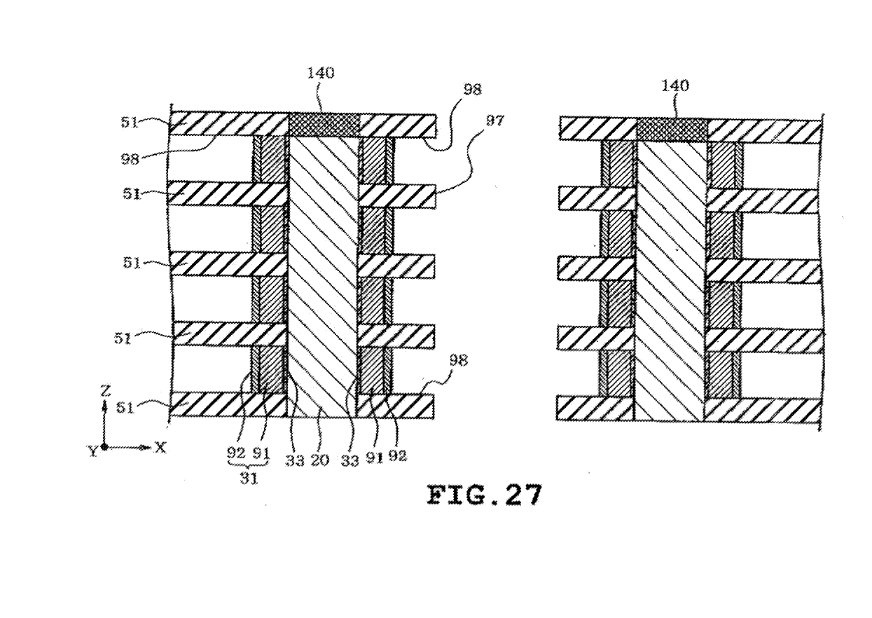

Next, a manufacturing method of a semiconductor memory device according to this embodiment will be described. FIG. 23 to FIG. 28 are examples of a cross-sectional view illustrating a manufacturing method of the three-dimensional NAND flash memory device 101 according to this embodiment. First, similar to the second embodiment described above, an insulating film 11, a source line SL, and an insulating film 17 are formed on a silicon substrate 10. Next, as illustrated in FIG. 24, the silicon oxide film 51 and the silicon nitride film 52 are alternately deposited, and a stacked body 53 is formed, and subsequently, a plurality of memory holes 95 are formed in the stacked body 53. Each memory hole 95 extends in the Z direction, passes through the stacked body 53 and the insulating film 17, and is connected to the source line SL.

Next, an exposed surface of the silicon nitride film 52 in an inner surface of the memory hole 95 is recessed by performing a wet etching. Accordingly, an annular recessed portion 96 is formed in the inner surface of the memory hole 95.

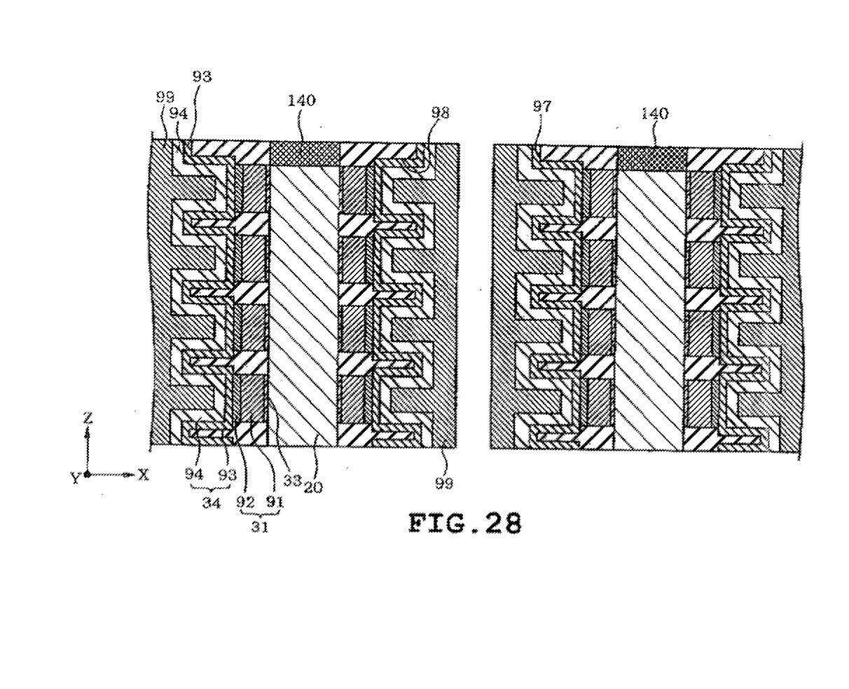

Next, polysilicon is deposited on the walls of the memory hole 95, and portions thereof are selectively removed by performing an isotropic etching step, and thus a polysilicon layer 91 is embedded in the recesses 96. Next, the surface of the polysilicon layer 91 exposed to the memory hole 95 is oxidized, and thus a tunnel insulating film 33 is formed. Subsequently, the silicon pillar 20 is formed by depositing polysilicon in the memory hole 95 to fill the memory hole 95. The silicon pillar 20 is connected to the source line SL in a lower portion. Next, germanium and carbon are implanted into a surface of the silicon pillar 20 by an ion implantation method, and the defect layer region 140 is formed as illustrated in FIG. 25. Furthermore, an upper portion of a region for forming the defect layer region 140 is covered with a resist provided with an opening by using a lithographic method, and an ion implantation may be locally performed only with respect to the region for forming the defect layer region 140.

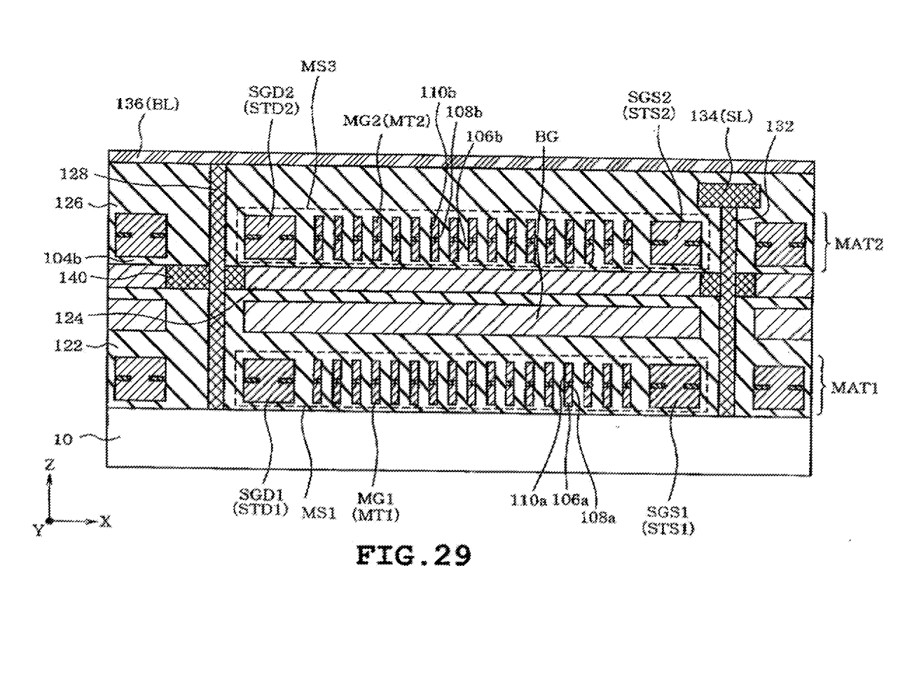

Next, as illustrated in FIG. 26, a trench 97 is formed through the stacked body 53 in a location between the memory holes 95. The trench 97 extends in the Z direction, and passes through the stacked body 53 in the Z direction.

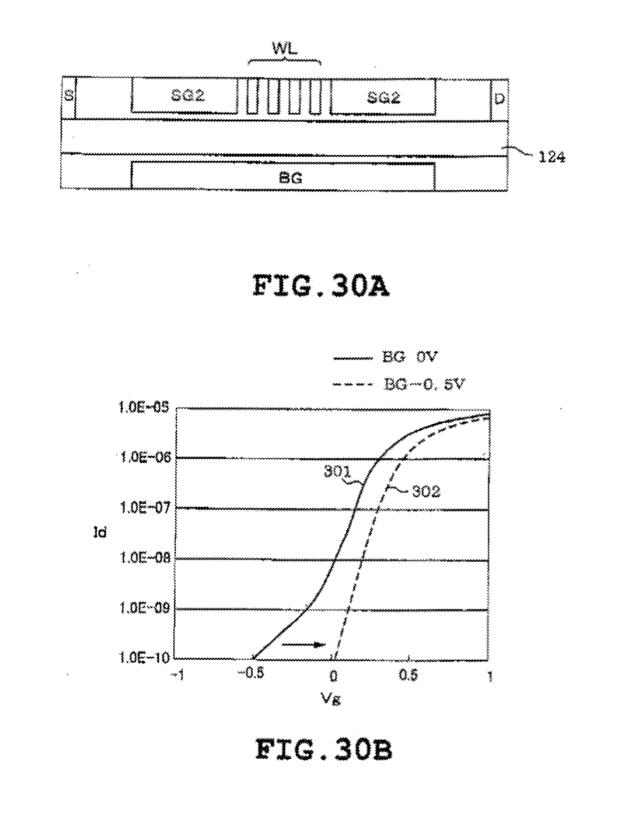

Next, the silicon nitride film 52 exposed in the trench 97 is removed by performing a wet etching. Accordingly, a concave portion 98 is formed in an inner surface of the trench 97 as illustrated in FIG. 27. The polysilicon layer 91 at the base of the concave portion is thus exposed. Subsequently, the exposed surface of the polysilicon layer 91 in the concave portion 98 is silicided through the trench 97 and the concave portion 98 by performing a silicide treatment. Accordingly, the metal silicide layer 92 is formed. The floating gate electrode film 31 is configured with the polysilicon layer 91 and the metal silicide layer 92.

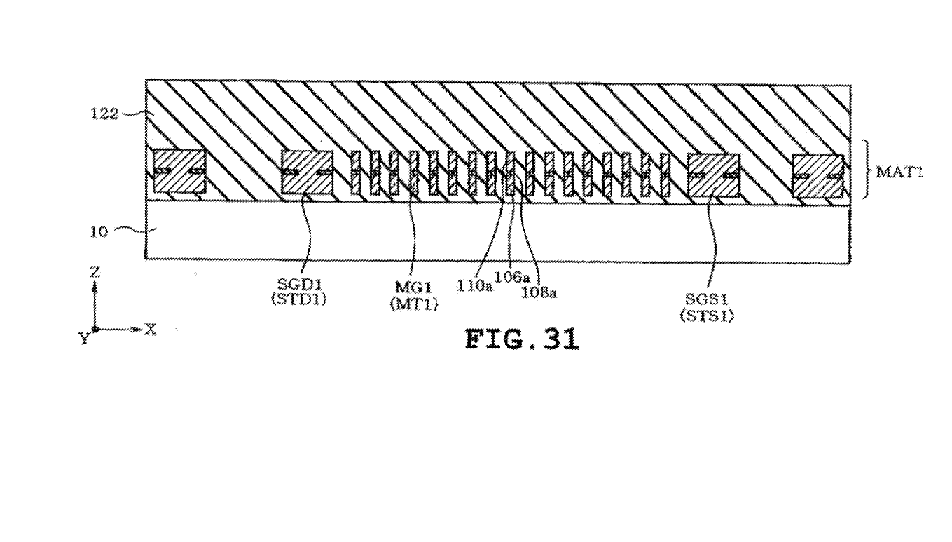

Next, the silicon oxide layer 93 is formed on the inner surface of the trench 97. Next, the high permittivity layer 94 is formed on the silicon oxide layer 93. The silicon oxide layer 93 and the high permittivity layer 94 are in the shape of a cylinder having a bellows shape by reflecting the concave portion 98. Subsequently, for example, an electrically conductive material is deposited by a CVD method, and thus a conductive film 99 is formed on the high permittivity layer 94. The conductive film 99 is formed to be embedded in the concave portion 98, but not to be embedded in the trench 97 as illustrated in FIG. 28.

Next, the conductive film 99 and the high permittivity layer 94 are recessed by performing an isotropic etching, and remain only in the concave portion 93a of the silicon oxide layer 93. Accordingly, the conductive film 99 remaining in the concave portion 93a is the control gate electrode film 21. In addition, the block insulating film 34 is formed by a residual portion of the high permittivity layer 94 and the silicon oxide layer 93. Subsequently, the interlayer insulating film 24 is formed in the trench 97. Thus, the three-dimensional NAND flash memory device 101 according to this embodiment is manufactured as illustrated in FIG. 23.

As described above, the defect layer region 140 is formed in the upper portion of the silicon pillar 20. The control gate electrode film 21 and the floating gate electrode in the uppermost portion of the silicon pillar 20 function as the selection gate electrode SG. Accordingly, the defect layer region 140 is a diffusion layer region on the bit line BL side and the source line SL side in the selection transistors STD and STS. Accordingly, when a reverse bias voltage is applied into the defect layer region 140, and an inter-band tunneling current is easily generated in a formed depletion layer. Accordingly, the same effect as in the first embodiment and the second embodiment is obtained.

Furthermore, in the third embodiment, a so-called I-shaped three-dimensional NAND flash memory device 101 is described as an example, and it is possible to apply a U-shaped three-dimensional NAND flash memory device 101 to the semiconductor memory device.

### Fourth Embodiment

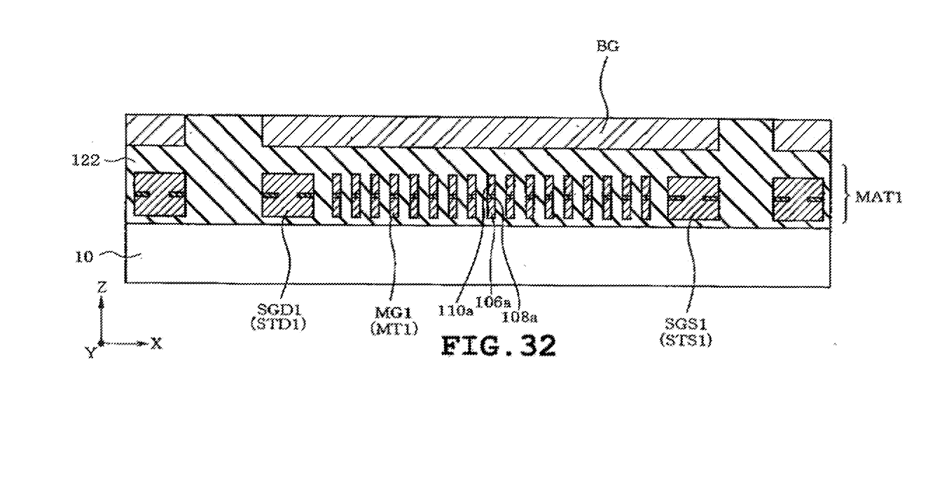

Next, a configuration according to a fourth embodiment will be described with reference to FIG. 29. FIG. 29 is an example of a longitudinal sectional view illustrating a structure of a simple stacked NAND flash memory device 100 according to the fourth embodiment. An example of an equivalent circuit diagram illustrating a part of a memory cell array formed in a memory cell region of the simple stacked NAND flash memory device 100 according to the fourth embodiment is identical to the equivalent circuit diagram illustrated in FIG. 2.

As illustrated in FIG. 29, a plurality of memory gates MG1, and selection gate electrodes SGD1 and SGS1 formed to either end of the string of memory gates MG1 therebetween are formed on a semiconductor substrate 10. The plurality of memory gates MG1, and the two selection gate electrodes SGD1 and SGS1 adjacent to the both ends of the plurality of memory gates MG1 form a memory string MS1. An inter-layer insulating film 122 covering an upper portion of the memory string MS1 is formed, and a back gate BG is formed in the upper portion. An insulating film is formed on the back gate BG, and a channel polysilicon layer 124 is formed in an upper portion of the insulating film. Further, a plurality of memory gates MG2, and two selection gate electrodes SG2 (SGD2 and SGS2) formed to interpose the plurality of memory gates MG2 therebetween are formed through the insulating film. The plurality of memory gates MG2, and the selection gate electrodes SG2 adjacent to either end of the plurality of memory gates MG2 form a memory string MS3. The back gate BG is formed to exist in a lower portion of the entire memory string MS3. A defect layer region 140 is formed in the channel polysilicon layer 124 positioned on the opposed ends of the memory string MS3.

A contact plug 128 (a bit line contact CB) and a contact plug 132 (a source line contact LI) extend through the interlayer insulating film 122 and a portion of the defect layer region 140 of the channel polysilicon layer 124 and reach a surface of the semiconductor substrate 10 in positions adjacent to the opposed ends of the memory string MS1. An electrode 130 is formed on the bit line contact CB, and wiring 136 (a bit line BL) is formed on the electrode 130 to be in contact with the electrode 130. Wiring 134 (a source line SL) is formed on the contact plug 132 to be in contact with the contact plug 132.

According to the configuration described above, in the simple stacked NAND flash memory device 100, when the memory string MS3 is a non-selection block at the time of performing data reading, it is possible to reduce a leakage current of selection transistors STD2 and STS2 using a selection gate electrode SG2 as a gate electrode, and thus it is possible to reduce a cutoff current. In addition, using the channel polysilicon layer 124, it is possible to shield an influence of a voltage from the memory gate MG1 of the memory string MS1 and the selection gate electrodes SGD1 and SGS1 in the lower layer, and thus it is possible to stabilize an operation of the memory string MS3 in an upper layer. Further, when the memory string MS3 is the non-selection block at the time of performing the data reading, cutoff characteristics of a memory cell transistor MT2 using the memory gate MG2 of the memory string MS3 as a gate electrode are improved. Accordingly, it is possible to reduce the leakage current of the entire non-selection block at the time of performing the data reading.

In the non-selection block at the time of performing the data reading, for example, it is possible to set the following bias condition.

Bit Line Contact CB: 0.25 (V)

Selection Gate Electrode SG (SGD, SGS): 0 (V)

Word Line WL (Memory Gate MG): 0 (V)

Source Line Contact LI: 0 (V)

Back Gate BG: −0.5 (V)

In addition, it is possible to use a plurality of word lines WL (a memory gate MG) adjacent to the selection gate electrodes SG as a dummy word line DWL, and in this case, 0 (V) is also applied to the dummy word line DWL.

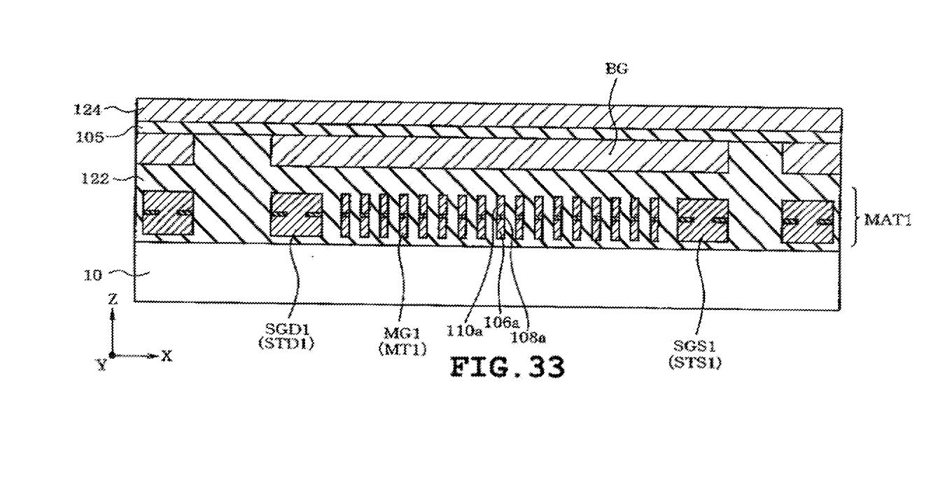

FIGS. 30A and 30B are diagrams illustrating a result of a simulation with respect to a change in the cutoff characteristics when a bias is applied to the back gate BG in a structure including the memory string MS2 and the back gate BG illustrated in FIG. 29. FIG. 30A illustrates the structure, and FIG. 30B illustrates the cutoff characteristics. As illustrated in FIG. 30A, the memory string MS2 illustrated in FIG. 29 is schematically configured in the structure where the simulation is performed. Here, the number of word lines WL (that is, the memory gate MG2) is 4. In FIG. 30B, a vertical axis indicates a drain current Id (A), and a horizontal axis indicates a gate voltage Vg (V) of the selection gate electrode SG2.

0 (V) is applied to the word line WL and the selection gate electrode SG2. The characteristics at the time of applying a bias voltage of 0 (V) to the back gate BG are illustrated by a graph line 301, and the characteristics at the time of applying a bias voltage of −0.5 (V) to the back gate BG are illustrated by a graph line 302. As illustrated in FIG. 30B, for example, in Vg=0 (V), the graph line 301 indicates that a current of approximately 1.0×10⁻⁸ (A) flows, but in the graph line 302, a current value is less than or equal to 1.0×10⁻¹⁰ (A). That is, it is understood that the cutoff characteristics of the entire memory string MS3 including the selection gate electrode SG2 and the memory gate MG2 are considerably improved.

In addition, according to this embodiment, the defect layer region 140 is disposed on one of the diffusion layer regions (on the side which is not adjacent to the memory gate MG) of the selection transistors STD and STS. Accordingly, the same effect as in the first embodiment is obtained.

(Manufacturing Method of Fourth Embodiment)

Next, a manufacturing method of a simple stacked NAND flash memory device 100 according to the fourth embodiment will be described with reference to the drawings. FIG. 29, and FIG. 31 to FIG. 33 are examples of a longitudinal sectional view illustrating configurations during a manufacturing process of a simple stacked NAND flash memory device 100 according to the fourth embodiment in a process sequence. First, the memory gate MG1, and the selection gate electrodes SGD1 and SGS1 are formed on the semiconductor substrate 10, and subsequently, the upper portion thereof is covered with the interlayer insulating film 126, and thus the upper portion is flattened as illustrated in FIG. 31.

Next, in an upper surface of the interlayer insulating film 126, a groove is formed in a region for forming the back gate BG in the following process. It is possible to form the groove, for example, by using a lithographic method and an RIE method. A position on which the back gate BG is formed is chosen in advance to be positioned directly below the memory gates MG2 and the selection gate electrode SGD2 and SGS2.

Subsequently, for example, a conductive film is formed on the entire surface including the inside of the groove, and the conductive film is removed by polishing until a surface of the interlayer insulating film 126 is exposed by using a CMP method, and a surface thereof is flattened. According to the process, the conductive film embedded in the groove is separated, and the back gate BG is formed as illustrated in FIG. 32. As the conductive film used as the back gate BG, for example, it is possible to use a metallic substance (for example, tungsten), polysilicon into which impurities are introduced, or the like. It is possible to form tungsten, for example, by using a CVD method. It is possible to form the polysilicon into which the impurities are introduced, for example, by a method in which the impurities are introduced while the polysilicon film is formed by a CVD method, or a method in which, for example, the impurities are introduced into the polysilicon by using an ion implantation method after the polysilicon film is formed.

Next, an insulating film 105 is formed on the back gate BG, and subsequently, the channel polysilicon layer 124 is formed as illustrated in FIG. 33. As the insulating film 105, for example, it is possible to use a silicon oxide film, and for example, it is possible to form the insulating film 105 by using a CVD method. As the channel polysilicon layer 124, for example, it is possible to use polysilicon, and for example, it is possible to form the channel polysilicon layer 124 by using a CVD method. P-type impurities (for example, boron) may be introduced into the channel polysilicon layer 124, and may not be doped.

Next, as illustrated in FIG. 29, an insulating film 104b is formed, and subsequently, the memory gate MG2, and the selection gate electrode SG2 are formed. As described above, the back gate BG is formed to be positioned below the memory gate MG and the selection gate electrode SG in advance. Further, the interlayer insulating film 126 is formed to cover the memory gate MG2 and the selection gate electrode SG2. Subsequently, wiring 134 and the contact plug 132, the electrode 130 and the contact plug 128 are formed. On an upper surface of the electrode 130, wiring 136 is formed to be in contact with the upper surface of the electrode 130. The wiring 134 is the source line SL, and the wiring 136 is the bit line BL.

According to the process described above, it is possible to form the simple stacked NAND flash memory device 100 according to this embodiment.

### Fifth Embodiment

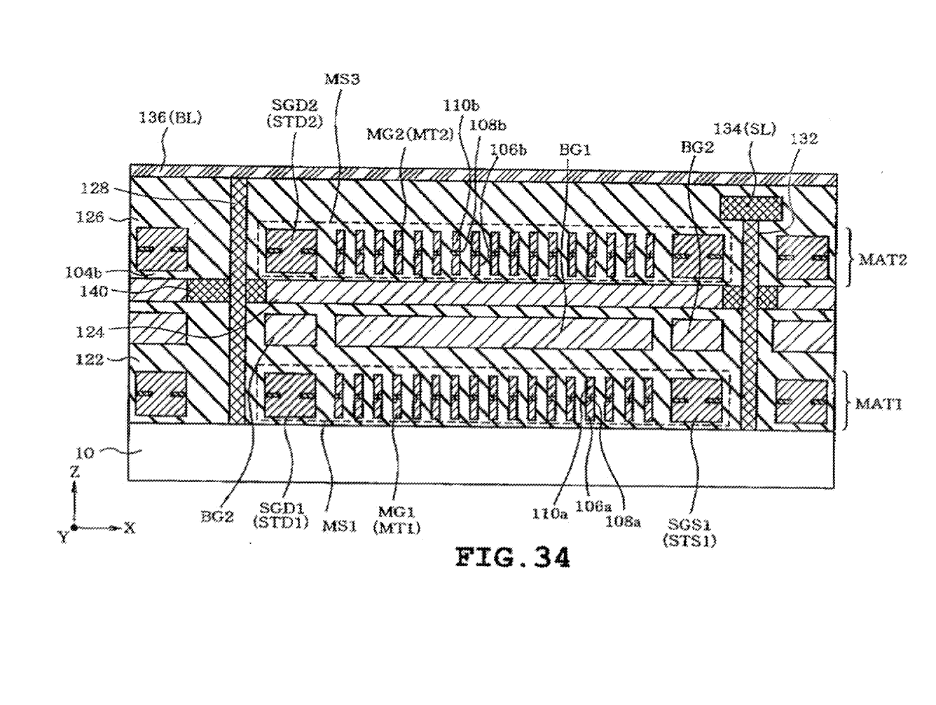

Next, a fifth embodiment will be described with reference to FIG. 34. FIG. 34 is an example of a longitudinal sectional view illustrating a structure of a simple stacked NAND flash memory device 100 according to the fifth embodiment. As illustrated in FIG. 34, in this embodiment, the back gate BG is divided into a back gate BG1 which is disposed to cover a lower portion of a plurality of memory gates MG2, and a back gate BG2 which is formed to be positioned below selection gate electrodes SGD2 and SGS2.

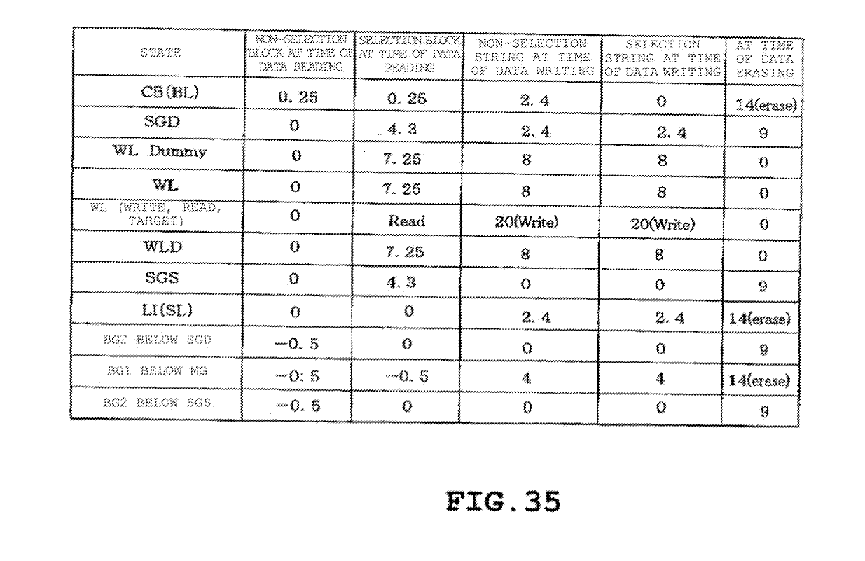

According to the configuration, it is possible to obtain the same effect as in the fourth embodiment. Further, it is possible to independently control a voltage to be applied to the back gate BG1 and the back gate BG2. Accordingly, for example, it is possible to apply a bias condition illustrated in FIG. 35, for example, to a non-selection block at the time of performing data reading, a selection block at the time of performing the data reading, a non-selection string at the time of performing data writing, a selection string at the time of performing the data writing, and each state at the time of performing data erasing.

In addition, in this embodiment, at the time of performing an erase operation, it is possible to apply the same voltage as applied to the selection gate electrodes SGD and SGS to the back gate BG2 below the selection gate electrodes SGD and SGS. Accordingly, it is possible to generate an interband tunneling current in a channel polysilicon layer 124 on the back gate BG2 side. That is, it is possible to generate the inter-band tunnelling current not only in an end of the selection gate electrodes SGD and SGS, but also in the channel polysilicon layer 124 on an end of the back gate BG2. Accordingly, generation efficiency of an electron and hole pair increases (in an ideal state, generation efficiency is doubled), compared to a case where the interband tunnelling current is generated only in the end of the selection gate electrodes SGD2 and SGS2, and thus it is possible to considerably shorten an erasing time.

In addition, in a NAND type flash memory device, it is necessary to inhibit erroneous write in a non-selected memory string at the time of performing the data writing. As characteristics required for this, it is necessary that a channel potential be raised and boosted up to a high potential, and the boosted potential be cutoff and not escape from a selection gate in the channel polysilicon layer 124. The back gate BG1 directly below the memory gate MG is depleted by applying a positive potential (for example, 4 V) to the back gate BG1, and thus a channel is easily completely depleted at the time of applying a voltage to the memory cell transistor MT, and it is possible to easily boost a channel portion.

At this time, when 4V is also applied to the back gate BG2 below the selection gate electrode SG, the cutoff characteristics of a selection transistor ST are degraded, and thus a boost leak occurs.

In this embodiment, the back gate BG is divided into the back gate BG1 which covers the lower portion of the plurality of memory gates MG2, and the back gate BG2 which is positioned below the selection gate electrodes SGD2 and SGS2. For this reason, it is possible to independently control the potential of the channel portion in the lower portion of the memory gate MG and the selection gate electrode SG (SGD2 and SGS2) by the back gates BG1 and BG2.

According to such a configuration, it is possible to realize improvement of the cutoff characteristics of the selection transistor ST (STD2 and STS2) using the selection gate electrode SG as a gate electrode, and also increase a boost effect of the channel portion below the memory gate MG.

In addition, according to this embodiment, the defect layer region 140 is disposed on one of the diffusion layer regions (on a side which is not adjacent to the memory gate MG) of the selection transistors STD and STS. Accordingly, the same effect as in the first embodiment is obtained.

### Sixth Embodiment

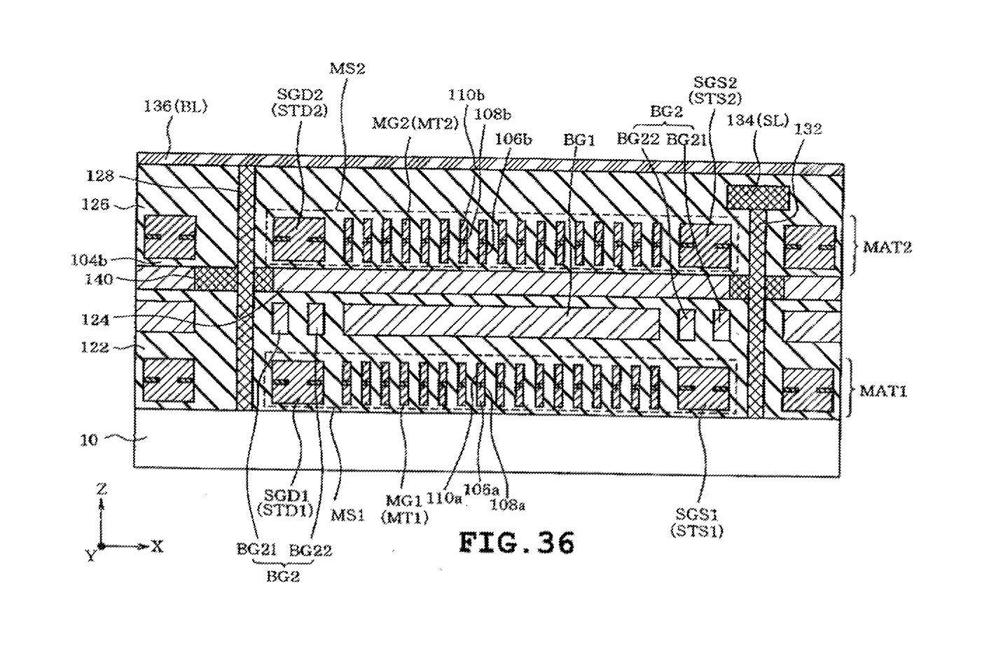

Next, a sixth embodiment will be described with reference to FIG. 36. FIG. 36 is an example of a longitudinal sectional view illustrating a simple stacked NAND flash memory device 100 according to the sixth embodiment. In the fifth embodiment described above, the back gate BG is divided into the back gates BG1 and BG2, but in the sixth embodiment, the back gate BG2 is further divided into back gates BG21 and BG22. The other configuration is identical to the configuration of the fifth embodiment.

According to such a configuration, it is possible to obtain the same effect as in the fifth embodiment. Further, the back gate BG2 below selection gate electrodes SGD and SGS is divided into the back gates BG21 and BG22, and thus it is possible to apply different voltages by the back gates BG21 and BG22, and it is possible to perform finer control.

In addition, according to this embodiment, a defect layer region 140 is disposed on one of diffusion layer regions adjacent to the opposed ends of the memory string (on a side which is not adjacent to a memory gate MG) of selection transistors STD and STS. Accordingly, the same effect as in the first embodiment is obtained.

### Seventh Embodiment

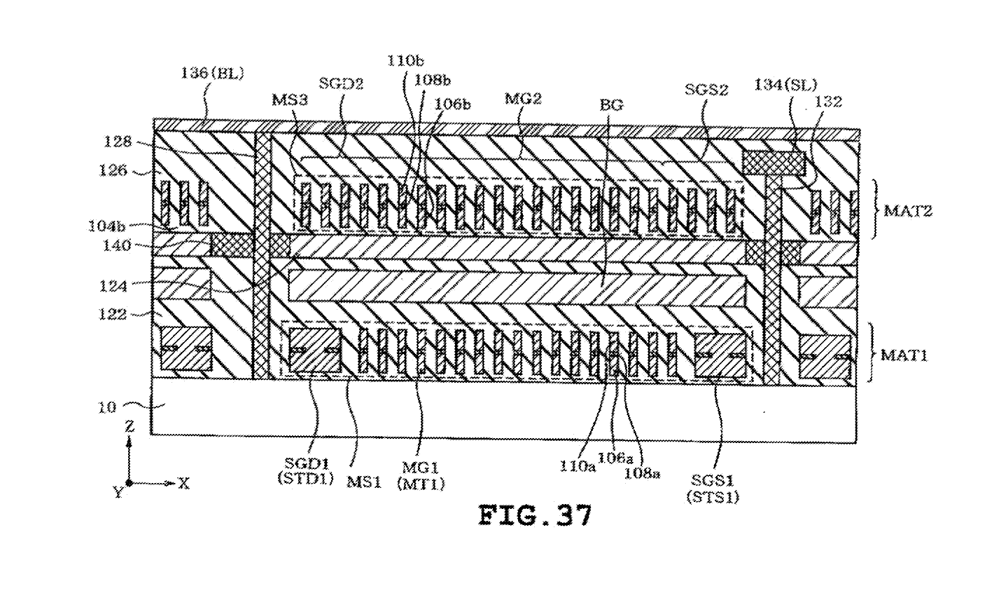

Next, a seventh embodiment will be described with reference to FIG. 37. FIG. 37 is an example of a longitudinal sectional view illustrating a structure of a simple stacked NAND flash memory device 100 according to the seventh embodiment. In the fourth embodiment described above, the memory gates MG2 and the selection gate electrodes SGD2 and SGS2 are formed having different dimensions, but in the seventh embodiment, a gate electrode corresponding to the selection gate electrodes SGD2 and SGS2 is formed to be a plurality of electrodes having the same dimension and the same structure as that of the memory gate MG2. Then, a plurality of end portions of the plurality of electrodes is set to selection gate electrodes SGD2 and SGS2 as a whole. FIG. 37 illustrates an example in which four electrodes having the same structure as that of the memory gates MG2 comprise the selection gate electrode SGD2. The remainder of the device configuration is identical to the configuration of the fourth embodiment.

According to such a configuration, it is possible to obtain the same effect as in the fourth embodiment. Further, the selection gate electrodes SGD2 and SGS2 have the same structure and dimensions as that of the memory gates MG2, and thus it is possible to form the selection gate electrodes SGD2 and SGS2 in the same processes as those forming the memory gate MG2, and thus the processing is easily performed and the number of process steps are reduced. In addition, when the gate electrode is in a fine dimension identical to that of the memory gate MG2, cutoff characteristics are degraded by a short channel effect, but by applying a voltage to the back gate BG, it is possible to improve the cutoff characteristics.

In addition, as in the fifth embodiment illustrated in FIG. 34, and the sixth embodiment illustrated in FIG. 36, the back gate BG may be divided into the back gates BG1 and BG2, and further, the back gate BG2 may be divided into the back gates BG21 and BG22. Accordingly, it is possible to obtain the same effect as in the fifth embodiment and the sixth embodiment.

In addition, according to this embodiment, the defect layer region 140 are provided on one of diffusion layer regions (on a side thereof which is not adjacent to a memory gate MG) of selection transistors STD and STS at opposed ends of the memory string. Accordingly, the same effect as in the first embodiment is obtained.

(Effect at the Time of being Used as Multivalued Memory)

Next, an effect at the time of using the simple stacked NAND flash memory device 100 of the fourth to the seventh embodiments described above as a multivalued memory will be described.

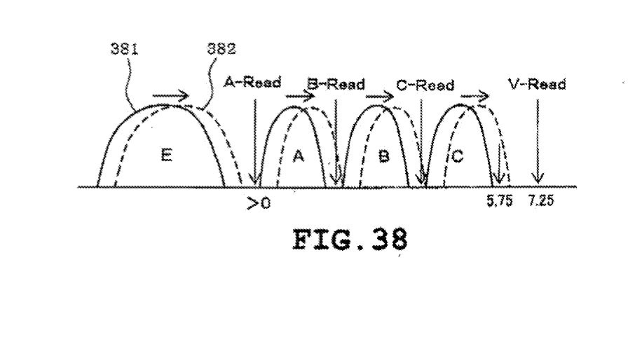

FIG. 38 is an example of a diagram illustrating an aspect of a variation in a plurality of threshold values at the time of using a stacked NAND flash memory device as a multivalued memory. A threshold value distribution at the time of not applying a bias to the back gate BG is illustrated by a graph line 381 (a solid line), and a threshold value distribution at the time of applying −0.5 (V) to the back gate BG is illustrated by a graph line 382 (a broken line). The threshold value distributions are set to threshold value distributions E, A, B, and C in order of increasing threshold voltage. The threshold value distributions E, A, B, and C are separated from each other. Each space between the threshold value distributions E, A, B, and C is set to a first read voltage A-Read, a second read voltage B-Read, a third read voltage C-Read, and a fourth read voltage V-Read.

In the NAND type flash memory device, only a voltage greater than or equal to 0 V is applied to the control gate of the word line WL. In the NAND type flash memory device, a memory cell having a negative threshold value is not able to be turned OFF. Accordingly, it is not possible to read out data stored in the memory cell which is turned ON at an applied voltage of the word line WL is 0 V.

In the description with reference to the graph of the threshold value distribution illustrated in FIG. 38, the first read voltage A-Read of a lowest voltage is set to be greater than or equal to 0 V. Accordingly, at the time of performing the data writing, the data writing is performed such that the applied voltage of the word line WL is turned ON at a voltage greater than or equal to 0 V.

However, a threshold value of the memory cell transistor approaches write saturation as a write threshold value increases, and thus write efficiency decreases. That is, a write voltage further increases as the data writing is performed at a high level, and thus erroneous writing in the threshold value distribution E rapidly increases. For this reason, it is difficult to make a margin of a distribution width by increasing the write threshold value. In such a restriction, it is necessary that the data writing is performed at three distinct distributions at the time of using a Multi Level Cell (MLC) method (for example, 5.75 V in 0 V to 5.75 V).

Here, when a voltage of −0.5 (V) is applied to the back gate BG, the entire threshold value distribution is shifted to a higher voltage value as illustrated by the graph line 382. Accordingly, when the voltage is not applied to the back gate BG (that is, when there is no back gate BG), a negative threshold value distribution which is not read in is also read in by disposing the back gate BG and by applying a bias to the back gate BG. That is, it is possible to widen a range of the threshold value distribution which is able to be read downwardly by a shift amount. When the range is upwardly widened, it is necessary to improve saturation characteristics of the memory cell transistor and to have a high write voltage, but when the range is downwardly widened as described above, it is not necessary to improve the saturation characteristics of the memory cell transistor and to have a high write voltage.

In addition, as illustrated in the fifth embodiment (FIG. 34), the structure where the back gate BG is divided into the back gate BG1 disposed below the memory gate MG, and the back gate BG2 disposed below the selection gate electrode SG, has the following effects. That is, when threshold values of the selection transistors STD2 and STS2 are changed by applying a voltage to the back gate BG (that is, the back gate BG which is integrally disposed below the memory gate MG2 and the selection gate electrode SG2) in the structure illustrated in FIG. 29, it is necessary that a voltage which allows the selection transistors STD2 and STS2 to be turned ON be changed. Accordingly, operational control becomes complicated. In the structure illustrated in FIG. 36, it is possible to independently control the voltage applied to the back gate BG1 and the voltage applied to the back gate BG2, and thus the operational control does not become complicated.

### Other Embodiment

In the embodiments described above, examples in which a NAND type flash memory device is applied to the semiconductor memory device are illustrated, and a NOR type flash memory device, and a nonvolatile semiconductor memory device such as an EPROM may be applied to the semiconductor memory device.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a plurality of memory strings, each including a plurality of memory transistors connected together in series and a selection transistor disposed at each end of the plurality of memory transistors connected together in series, wherein the memory transistors and the selection transistors each include a polysilicon layer formed on an insulating film as a channel region thereof;
a drain region in a first diffusion layer region in the polysilicon layer in a location adjacent to a first one of the selection transistors at a first end of the memory string; and
a source region in a second diffusion layer region in the polysilicon layer in a location adjacent to a second one of the selection transistors at a second end of the memory string, wherein
in at least one of the first and the second diffusion regions, the grain size of the polysilicon is substantially smaller than in other portions of the polysilicon.

2. The device according to claim 1, wherein the region of the polysilicon layer having a smaller grain size than the other portions of the polysilicon layer contains germanium.

3. The device according to claim 1, wherein the region of the polysilicon layer having a smaller grain size than the other portions of the polysilicon layer contains more crystal defects than other portions of the polysilicon layer.

4. The device according to claim 1, wherein the region of the polysilicon layer having a smaller grain size than the other portions of the polysilicon layer contains carbon.

5. The device according to claim 1, wherein the region of the polysilicon layer having a smaller grain size than the other portions of the polysilicon layer contains more electron-hole pair generation and recombination centers than the other portions of the polysilicon layer.

6. The device according to claim 1, wherein the grain size of the polysilicon layer which is located adjacent to the gate electrodes of the memory transistors and the selection transistors is greater than the grain size of the at least one of the first and the second diffusion regions.

7. The device according to claim 1, further comprising:
an insulating film formed on the first memory string, and
a second memory string over the insulating film, the second memory string including a plurality of second memory transistors connected in series, and second selection transistors disposed at opposed ends of the plurality of second memory transistors connected in series.

8. The device according to claim 1, wherein an air gap is formed between the gate electrodes of the memory transistors.

9. The device according to claim 1, wherein each memory transistor includes a portion of a semiconductor pillar extending from a semiconductor substrate.

10. The device according to claim 9, wherein the semiconductor pillar comprises the channel regions of the memory transistor and the selection transistors.

11. A nonvolatile semiconductor memory device, comprising:
a plurality of memory strings, each including a plurality of memory transistors connected together in series and selection transistor disposed at each end of the plurality of memory transistors connected together in series, wherein
the memory transistor and the selection transistors each include a polysilicon layer formed on an insulating film as a channel region, and
an electrode is disposed on the other side of the polysilicon layer and the insulating film with respect to the plurality of memory transistors which are connected in series.

12. The device according to claim 11, wherein the electrode is further disposed below at least one of the first and second selection transistors.

13. The device according to claim 12, wherein the electrode includes a first electrode located below the plurality of memory transistors connected in series, and a second electrode located below at least one of the first and the second selection transistors.

14. The device according to claim 12, wherein the second electrode comprises a separate electrode located between each of the first and the second selection transistors.

15. The device according to claim 11, wherein at least one of the first and the second selection transistors comprises a plurality of gate electrodes having substantially the same structure as a structure of a gate electrode of a memory transistor in the memory cell.

16. The device according to claim 15, wherein the electrode extends below the plurality of memory transistors connected in series and the first and the second selection transistors disposed on the opposed ends of the plurality of memory transistors.

17. The device according to claim 16, wherein the electrode comprises a first electrode extending below the plurality of memory transistors connected in series, and a second electrode extending below each of the first and the second selection transistors.

18. The device according to claim 17, wherein the second electrode comprises two electrodes.

19. The device according to claim 11, wherein the polysilicon layer further comprises a diffusion layer region of at least one of the first and the second selection transistors, the diffusion layer region located on a side of the at least one of the first and the second selection transistors opposed to the side thereof adjacent to a memory transistor, and
the polysilicon of the polysilicon layer comprising the diffusion layer has a substantially smaller grain size than in other portions of the polysilicon layer.

20. A method of manufacturing a semiconductor device, comprising:
providing a polysilicon layer;
providing a memory string on the polysilicon layer, the memory string comprising a plurality of memory transistors connected in series, and a selection transistor located at both ends of the plurality of memory transistors connected in series;
forming source and drain regions in the polysilicon layer; and
reducing the grain size of the polysilicon layer in a region thereof adjacent to at least one of selection transistors on a side of the selection transistor not adjacent to a memory transistor.
